(19) United States
(12) Patent Application Publication
(10) Pub. No.: US 2025/0120318 A1
(43) Pub. Date: Apr. 10, 2025

(54) ATOMIC LAYER ETCHING OF MGO-DOPED LITHIUM NIOBATE USING SEQUENTIAL EXPOSURES OF H2 AND SF6/ARGON PLASMAS

(71) Applicant: California Institute of Technology, Pasadena, CA (US)

(72) Inventors: Harold Frank Greer, Los Angeles, CA (US); Jenni Solgaard, Pasadena, CA (US); Ivy Chen, Pasadena, CA (US); Austin Minnich, San Marino, CA (US); Alireza Marandi, Pasadena, CA (US); Ryoto Sekine, Pasadena, CA (US)

(73) Assignee: California Institute of Technology, Pasadena, CA (US)

(21) Appl. No.: 18/908,317

(22) Filed: Oct. 7, 2024

Related U.S. Application Data
(60) Provisional application No. 63/542,879, filed on Oct. 6, 2023.

(51) Int. Cl. H10N 30/082; H01L 21/67

(52) U.S. Cl. CPC H10N 30/082; H01L 21/67069

(57) ABSTRACT

Lithium niobate (LiNbO₃, LN) is a ferroelectric crystal of interest for integrated photonics owing to its large second-order optical nonlinearity and the ability to impart periodic poling via an external electric field. However, on-chip device performance based on thin-film lithium niobate (TFLN) is presently limited by propagation losses arising from surface roughness on the nano- and microscale. Atomic layer etching (ALE) can smooth these features and thereby increase photonic performance. In one embodiment disclosed herein, an isotropic ALE process for x-cut MgO-doped LN uses sequential exposures of H₂ and SF₆/Ar plasmas. We observed an etch rate of 1.59±0.02 nm/cycle with a synergy of 96.9%. ALE can be achieved with SF₆/O₂ or Cl₂/BCl₃ plasma exposures in place of the SF₆/Ar plasma step with synergies of 99.5% and 91.5% respectively. The process decreased the sidewall surface roughness of TFLN waveguides etched by physical Ar⁺ milling by 30% without additional wet processing.

### CROSS REFERENCE TO RELATED APPLICATIONS

This application claims the benefit under 35 U.S.C. Section 119(e) of U.S. Provisional Application No. 63/542,879, filed Oct. 6, 2023, by Harold Frank Greer, Jenni Solgaard, Ivy Chen, Austin Minnich, Alireza Marandi, and Ryoto Sekine, entitled “Quasi-Atomic Layer Etching of X-Cut Mgo-Doped Lithium Niobate Using Sequential Exposures of H2 And Sf6 Plasma,” (CIT 9076) which application is incorporated by reference herein.

### BACKGROUND OF THE INVENTION

### 1. Field of the Invention

The present disclosure relates to atomic layer etching of lithium niobate and devices and methods using the same.

### 2. Description of the Related Art

Lithium niobate (LiNbO3, LN) is a platform for integrated photonics. Recent demonstrations of record on-chip quantum states, >100 GHz electro-optic modulators with CMOS compatible voltages, and multi-octave frequency combs with 100 fJ pump pulse energies highlight the potential of this platform to enable novel on-chip photonic functionalities.

The standard technique used for nanophotonic LN waveguide fabrication is Ar+ milling. However, thin-film lithium niobate (TFLN) devices suffer from large scattering losses resulting from the surface roughness left by the Ar+ milling, which negatively impacting device performance. What is needed, then, are improved methods for fabricating LN devices. The present invention satisfies this need.

### SUMMARY OF THE INVENTION

The present disclosure reports on atomic layer etching of a substrate comprising lithium niobate. The method comprises exposing the lithium niobate in an ALE reactor to a reactant that combines with the lithium niobate to form a compound in a modified layer; optionally purging the reactor using an inert gas; removing the modified layer using a removal agent, wherein the modified layer is removed at a higher rate than the lithium niobate; and optionally purging the reactor using an inert gas.

An illustrative isotropic ALE process for Magnesium Oxide (MgO)-doped x-cut LN comprises sequential exposures of H₂ and SF₆/Ar plasmas for which we measure an etch per cycle (EPC) of 1.59±0.02 Å/cycle with a synergy of 96.9%. We observed the saturation of both half-steps of the process. While surface roughness is observed to increase on flat surfaces, a 57% reduction in surface roughness on waveguide sidewalls is observed after 50 cycles of ALE. In addition, we demonstrate that the SF₆/Ar plasma step can be replaced with an O₂/SF₆ or Cl₂/BCl₃ plasma and achieve EPCs of 2.24±0.02 and 1.65±0.03 and synergies of 99.5% and 91.5%, respectively.

The present disclosure shows that manufacturing of LN devices using Atomic layer etching (ALE) can mitigate scattering losses due to its ability to smooth surfaces to sub-nanometer length scales. In one embodiment, the ALE process can be used to smooth sidewall surfaces of TFLN waveguides as a post-processing treatment (e.g., after Ar⁺ milling to smoothen sidewall roughness and corrugations in periodically-poled TFLN devices) thereby increasing the performance of TFLN nanophotonic devices and enabling new integrated photonic device capabilities.

Illustrative embodiments of the present invention include, but are not limited to, the following.

1. A method of etching lithium niobate, comprising:
etching a substrate comprising lithium niobate using atomic layer etching.

2. The method of clause 1, wherein the etching comprises patterning a photonic integrated circuit or one or more device structures in the lithium niobate and/or smoothing the surface of one or more device structures that have been patterned by another process.

3. The method of clause 1 or 2, further comprising:
obtaining the substrate covered with a patterned resist layer exposing regions of the lithium niobate to be etched; and
etching the exposed regions using the atomic layer etching.

4. The method of any of the clauses 1-3, wherein the etching comprises:
(a) Bombarding the lithium niobate with (or exposing the lithium niobate to) a hydrogen plasma comprising protons accelerated by a bias in an ALE reactor, to form a modified layer on the lithium niobate substrate;
(b) purging the reactor using an inert gas;
(c) removing the modified layer using a removal agent; and
(d) purging the reactor using an inert gas.

5. The method of any of the clauses 1-4, wherein the etching comprises:
(a) exposing the lithium niobate to a reactant that combines with the lithium niobate to form a compound;
(b) optionally purging the reactor using an inert gas;
(c) removing the modified layer using a removal agent, wherein the modified layer is removed at a higher rate than the lithium niobate; and
(d) optionally purging the reactor using an inert gas.

6. The method of any of the clauses 4-5, wherein the removing comprises sputtering using chemical species or using ions accelerated by a bias under conditions that remove the modified layer over the bulk lithium niobate in a self-limiting process.

7. The method of any of the clauses 4-6, wherein the removing comprises exposing the modified layer to the removal agent comprising chlorine or fluorine as a neutral species or in a plasma as an ionic species accelerated by a bias.

8. The method of any of the clauses 4-7, wherein the inert gas comprises argon.

9. The method of any of the clauses 4-8, further comprising performing multiple cycles of step (a) and (b) prior to performing step (c).

10. The method of clause 8, further comprising performing multiple cycles of step (a) and (c).

11. The method of any of the clauses 1-10, wherein the etched surface is etched with nanometer resolution (or with a surface roughness less than 3.5 nm, less than 2 nm, less than 1.5 nm, or less than 1 nm, and/or the etched surface is smoother than the non etched regions).

12. The method of any of the clauses 1-11, further comprising one or more cycles of:
(a) exposure of the substrate to a dose of the hydrogen plasma for a duration and under a bias and temperature and pressure such that the hydrogen adsorbs on a surface of the substrate in a self limiting process as characterized by the hydrogen saturating all available reactive bonding sites with the lithium niobate to form a modified layer; and
(b) exposure of the modified layer to a dose of the chemical species comprising a halogen at a temperature, pressure and energy such that the chemical species selectively removes the modified layer over the underlying bulk lithium niobate in a self-limiting process; and such that removal of one or more atomic layers of the lithium niobate after each cycle can be controlled with precision of a single one of the atomic layers.

13. The method of any of the clauses 5-12, wherein the photonic integrated circuit or device structure includes at least one of a waveguide or resonator (e.g., less than 5 micron wide and 1 micron deep).

14. The method of any of the clauses 5-13, wherein the ALE is performed on an x-cut surface of the lithium niobate.

15. The method of any of the clauses 4-13, further comprising controlling an angle of incidence or angular distribution of the removal agent on the substrate by controlling at least one of the temperature or pressure or bias, so as to control anisotropy and/or inclination of the etched surface and crystal quality of the etched lithium niobate.

16. The method of any of the clauses 1-15, wherein the removing comprises a selective process that removes redeposited species (such as Li, Mg) without etching the lithium niobate in the substrate.

17. The method of clause 15, wherein the removing comprises thermal cycling or wet etching using a liquid removal agent.

18. The method of clause 5, further comprising selecting an angle of incidence or angular distribution of the reactant/and or removal agent on the substrate to etch and/or smoothen sidewalls of a waveguide or structure comprising the lithium niobate.

19. The method of clause 4, wherein the removal agent comprises SF6/argon (e.g., ions or plasma).

20. A device comprising:
a structure patterned into a lithium niobate substrate using atomic layer etching, or
a structure comprising lithium niobate having a surface (e.g., of a sidewall, an inclined sidewall (e.g., more than 30 degrees), or cross-section) smoothened using atomic layer etching.

21. The device of clause 13, wherein the surface comprises hydrogen, an amorphized layer of the lithium niobate, and a surface roughness less than 3.5 nm.

22. A device comprising:
a structure patterned into a lithium niobate, wherein a surface of the lithium niobate comprises at least one of hydrogen, an amorphized or amorphous layer, or a surface roughness less than 3.5 nm or less than 1.5 nm.

23. The device of clause 16, wherein the surface is an x-cut surface optionally comprising magnesium oxide.

24. An atomic layer etching apparatus:
a source of a reactant for reacting with a surface of a substrate so as to form a modified layer on the substrate, wherein the reactant is generated by a plasma, and the substrate comprises lithium niobate;
a source of a treatment for removing the modified layer; and
a computer comprising a non-transitory computer readable medium storing a plurality of instructions, the plurality of instructions comprising:
outputting the reactant in the reactor tool, outputting the treatment to remove the modified layer so as to etch and/or smooth features in the lithium niobate.

25. The method or apparatus of any of the clauses 5-24, wherein the removal agent and reactant are provided under conditions that create and remove the modified layer, respectively, as self-limiting processes.

### BRIEF DESCRIPTION OF THE DRAWINGS

The patent or application file contains at least one drawing executed in color. Copies of this patent or patent application publication with color drawing(s) will be provided by the Office upon request and payment of the necessary fee Referring now to the drawings in which like reference numbers represent corresponding parts throughout:

FIG. 1a. Process Flow for manufacturing an LN device using Atomic Layer Etching.

FIG. 1b. Example test etch pattern.

FIG. 1c. Example ALE reactor modified from: https://www.researchgate.net/figure/Schematic-of-the-ICP-system-Oxford-Instruments-PlasmaPro-System100-Cobra-used-to-etch_fig2_319882281 and [78].

FIG. 2. Example generalized process flow for performing ALE.

FIG. 3. Example process flow for performing ALE using example reactants. A hydrogen plasma exposure leads to a hydrogen-rich modified layer (pink circles) at the top of the sample (blue dots), followed by a purge. A subsequent SF₆/Ar plasma exposure (yellow dots) yields volatile species. A final purge completes the cycle. Lithium niobate structure can be found in [77]

FIG. 4a. Photograph of a surface of an LN substrate after the formation of the modified layer.

FIG. 4b-4c. Microscope images (10× magnification in FIG. 4c) of the developed lithography pattern on the LN wafer. The dotted line indicates the direction of AFM scan for etch depth measurements in the additional results section.

FIG. 5a-5c. AFM images (FIG. 5a-5b) of the surface the LN substrate after the formation of modified layer using the tabulated process conditions in FIG. 5c.

FIG. 6. Height measurement of the modified layer as a function of the number of H₂ or H₂/Ar ion cycles.

FIG. 7a-7c. Line scans across the surface of the modified layer (hydrogen only FIG. 7a and hydrogen and argon in FIG. 7b at the location shown in the AFM image of FIG. 7c.

FIGS. 7d-7e. RHEED images for untreated bulk LN (FIG. 7d) and treated bulk LN (FIG. 7e).

FIGS. 7f-7g. SIMS data for hydrogen to oxygen ratio (FIG. 7f) and lithium to oxygen ratio (FIG. 7g) FIG. 8. Tabulated data characterizing the removal of the modified layer using chlorine and fluorine.

FIG. 9. XPS data of the fluorine treated substrate.

FIG. 10a-10c. AFM images (FIGS. 10a-10b) and line scan (FIG. 10c) of the final ALE etched surface.

FIGS. 11a-11c. (a) EPC versus cycle number with 40 second H₂ plasma exposures only (blue triangles), 40 second SF₆/Ar plasma exposures only (red squares), and both half-cycles (purple circles). All processes occur at 0° C. The dashed lines are guides to the eye. (b) EPC versus H₂ plasma exposure time with SF₆/Ar plasma exposure time fixed at 30 s. (c) EPC versus SF₆/Ar plasma exposure time with H₂ plasma exposure time fixed at 30 s. The etch rates are observed to saturate with exposure time, demonstrating the self-limiting nature of the process.

FIGS. 12a-12e. Surface XPS spectra showing (a) Nb3d, (b) O1s, (c) F1s spectra, and (d) Nb4s, Li1s, Mg2p. The spectra is shown for (top) original and (bottom) etched bulk MgO-doped LN over 50 ALE cycles consisting of a 40 second H₂ plasma exposure followed by a 40 second SF₆/Ar exposure. The measured (blue dots) and fit spectra (gray lines) intensity are reported in arbitrary units (a.u.) against the binding energy on the x-axis. (e) Surface atomic concentration normalized by carbon atomic concentration from XPS spectra for each sample for untreated bulk LN, 1 cycle H₂ plasma exposure, 10 ALE cycles, and 50 ALE cycles.

FIGS. 13a-13d. AFM scan showing height-maps of TFLN waveguide sidewall with linear-plane tilt removal before (a) and after 50 ALE cycles (b). (c) Averaged AFM line scans of the TFLN waveguide side profile before and after 50 cycles ALE. The waveguide width decreases by 50 nm on each side, yielding a lateral etch rate of 1 nm/cycle, which is comparable to the vertical etch rate of 1.59 nm/cycle measured on bulk LN. (d) Height-map PSD of the samples before ALE and after 50 cycles of ALE.

FIG. 14. Flowchart illustrating a method of atomic layer etching.

FIG. 15a Microscope image at 10× magnification of microring resonator on which ALE could be applied.

FIG. 15b. Microscope image at 10× magnification of the side of an optical parametric amplifier on which ALE could be applied.

FIG. 16a. Schematic of Racetrack resonator (striped portion is periodically poled) on which ALE could be applied. See also FIG. 1a in [76].

FIG. 16b. Cross section of a waveguide showing sidewalls and top surface on which smoothing/etching using ALE could be performed.

FIG. 17. Example Hardware environment.

FIG. 18. Example Network Environment.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

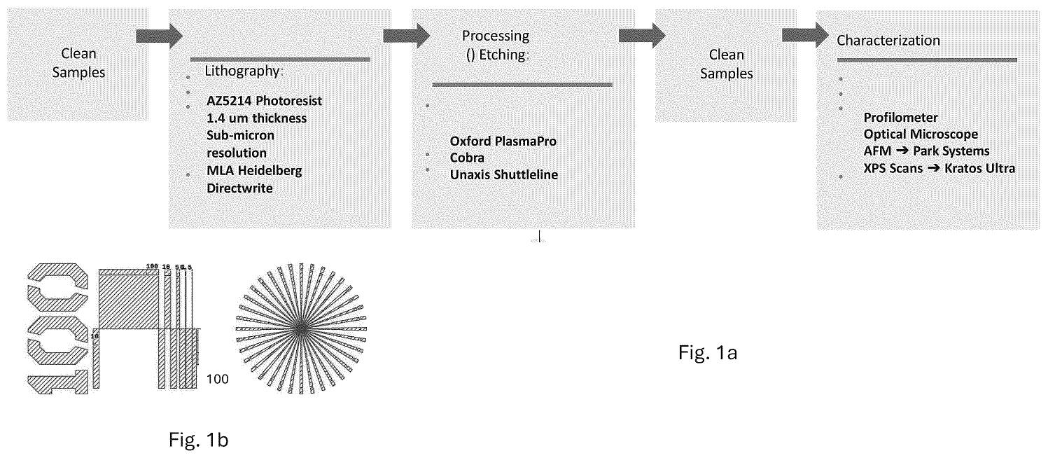

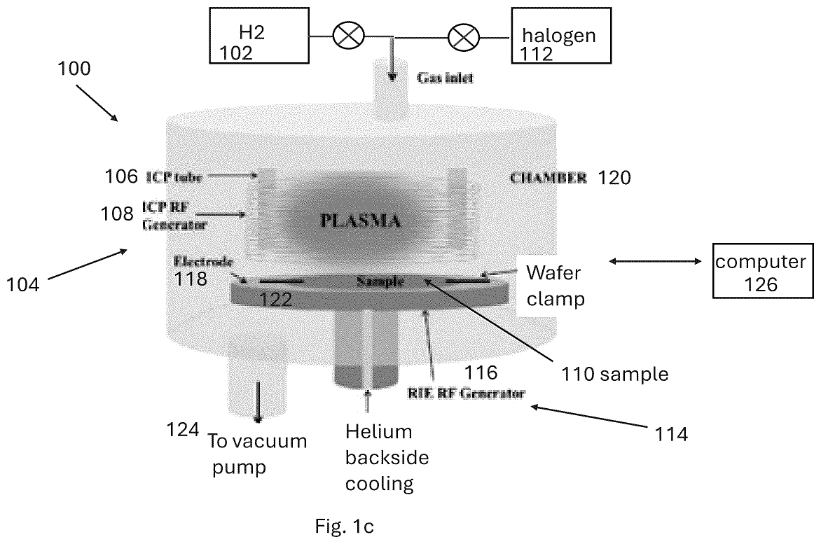

FIG. 1 illustrates a method of etching a substrate comprising lithium niobate using atomic layer etching, e.g., for patterning or smoothing device structures in the lithium niobate. The method comprises obtaining a cleaned substrate covered with a patterned resist layer exposing regions of the lithium niobate to be etched; and processing (e.g., etching) the exposed regions using the atomic layer etching.

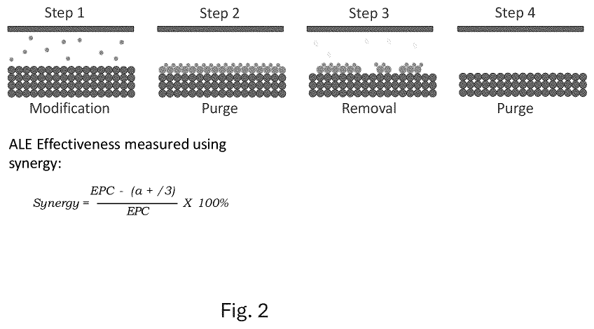

FIG. 2 illustrates the etching comprises, in step 1, exposing the lithium niobate to a reactant that combines with the lithium niobate to form a compound in a modified layer, purging the reactor using an inert gas such as, but not limited to, argon (step 2); removing the modified layer using a removal agent, wherein the modified layer is removed at a higher rate than the lithium niobate (step 3); and purging the reactor using an inert gas (step 4).

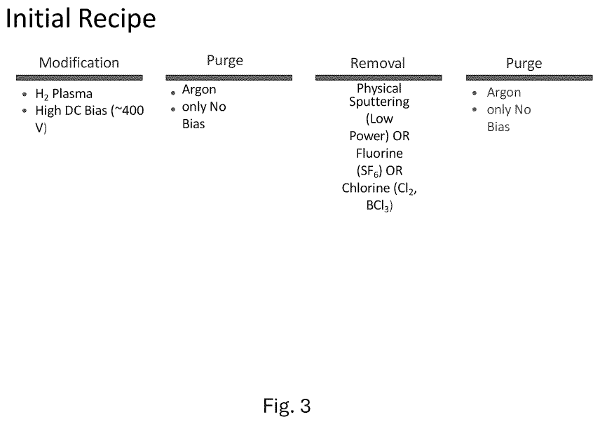

In one embodiment, step 1 forming the modified layer comprises a proton exchange process, e.g., bombarding the lithium niobate with a hydrogen and plasma comprising protons accelerated by a bias in an ALE reactor, to form the modified layer on the lithium niobate substrate. In lithium niobate, the proton in lithium atoms can be swapped out for hydrogen atoms (see FIG. 3) and this process changes properties such as refractive index. Thus, the etching process can be tailored for highly selective removal and treatment of lithium niobate to spatially control the refractive index.

Atomic layer etching can be performed in self-limiting cycles rather than continuously for increased control of dimensions and or smoothness. Increased precision in the dimensions of the waveguides in optical circuits facilitates dispersion engineering (which is controlled by the dimensions of the waveguide). Increased smoothness decreases scattering loss in waveguides or other optical components. Improved geometry allows for steeper sidewalls and less micro-trenching which can lead to improved waveguide confinement.

### Example Results

### 1. Modified Layer

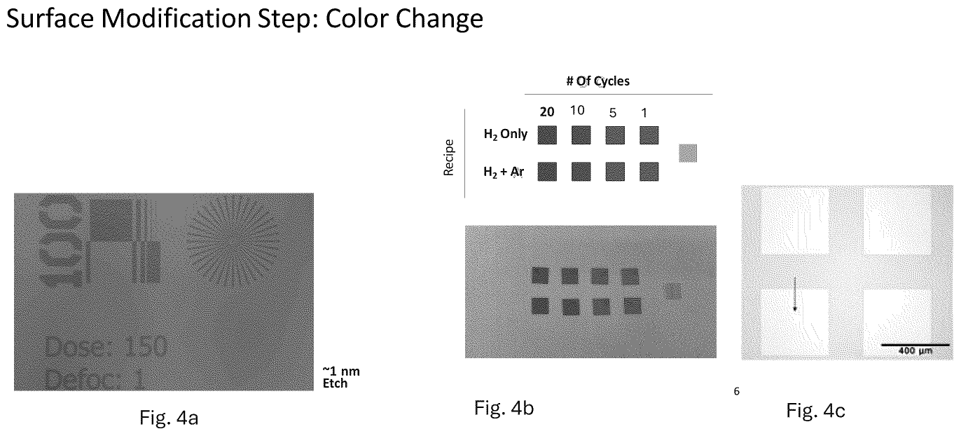

FIG. 4 is a photograph of the surface of a lithium niobate substrate treated with a hydrogen plasma and sputtering with argon ions in step 1, showing the treatment results in a color change of the surface in the patterned areas exposed to the hydrogen plasma and sputtering.

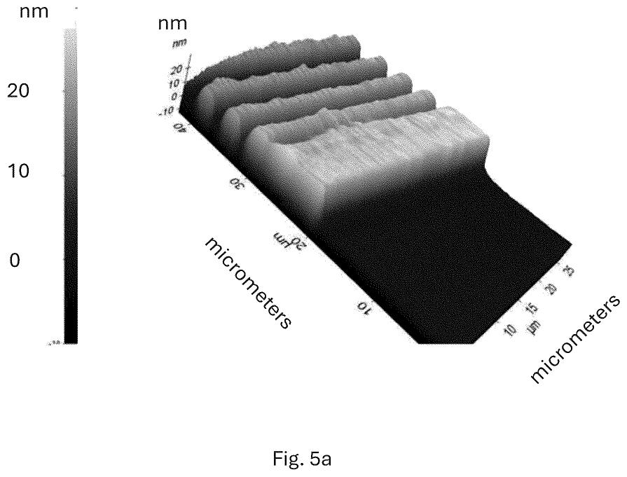

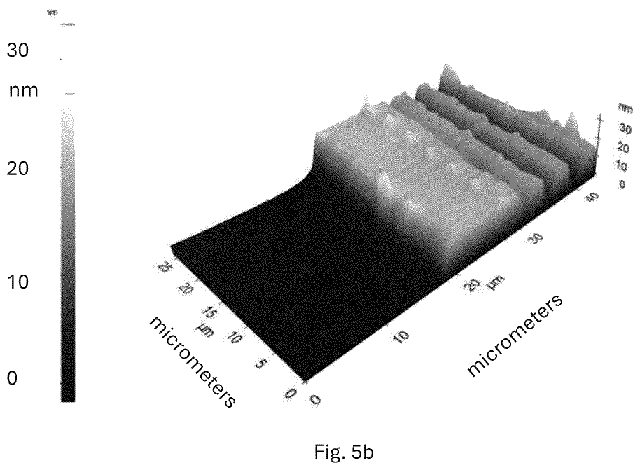

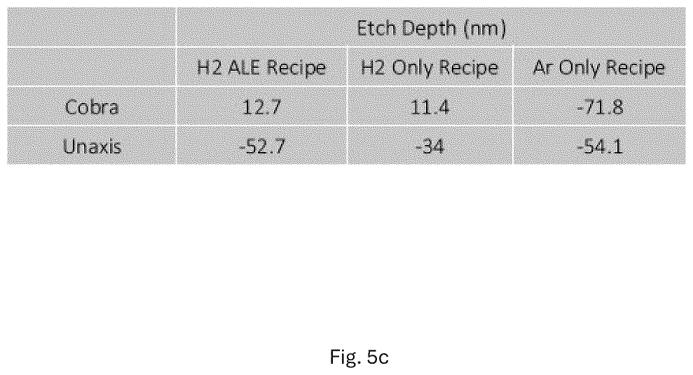

FIG. 5 are AFM images showing the surface modification step 1 raised height/elevation of features in the exposed/modified regions. Higher temperature resulted in higher elevation.

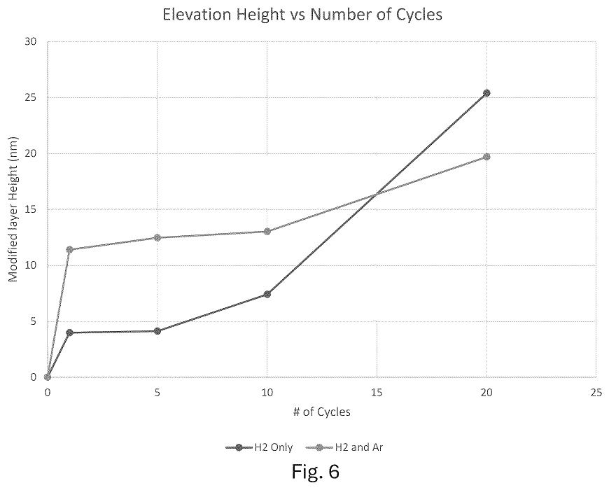

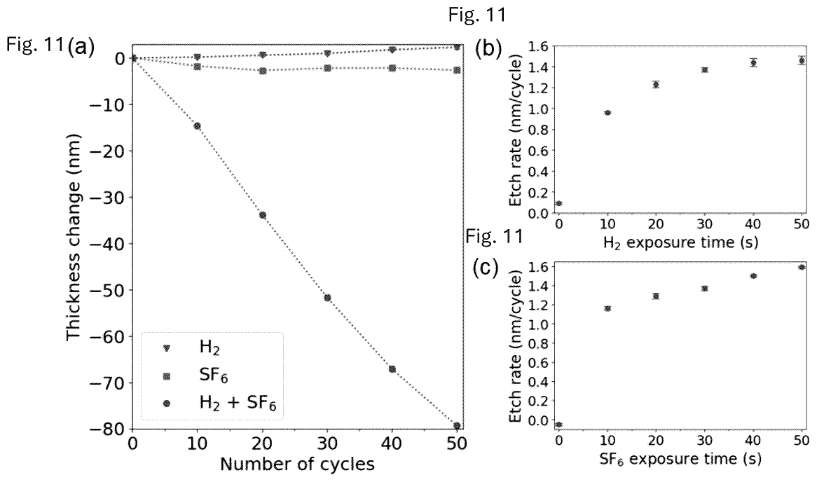

FIG. 6 shows the measured elevated height after step 1 using 1, 5, 10, 20 cycles for H₂ only and H₂ followed by argon bombardment. The use of H₂ only does not result in a self-limiting process for these numbers of cycles. However, the process may be rendered self-limiting by tuning the direct current (DC) Bias or tuning the plasma exposure time. FIG. 11b shows the H₂ exposure forms the modified layer and achieves saturation after tuning of the plasma exposure time. When using H₂/Ar cycles in step 1, the process saturates quickly.

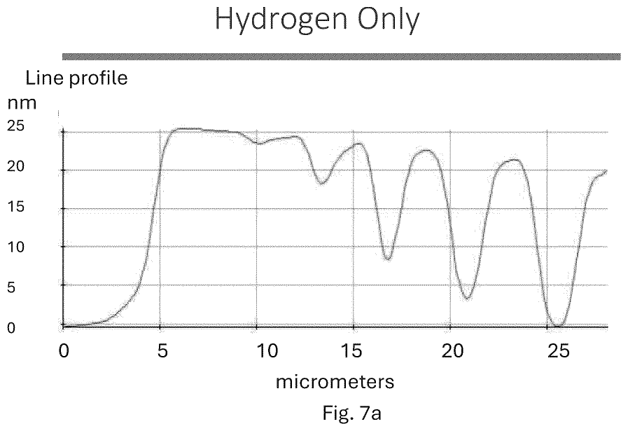

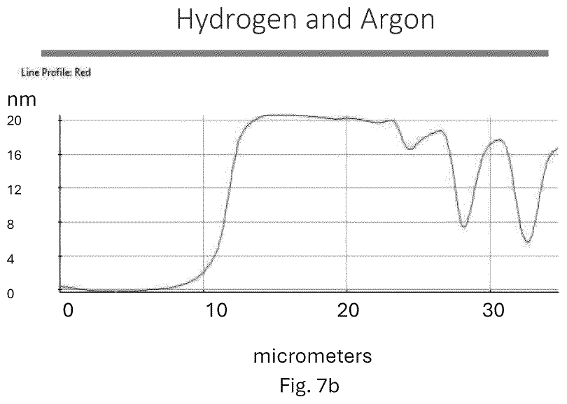

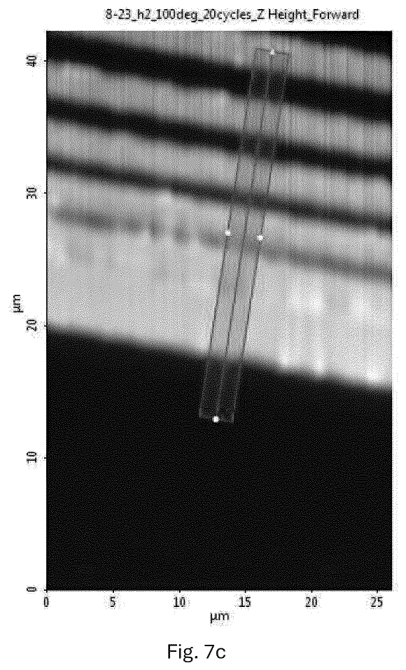

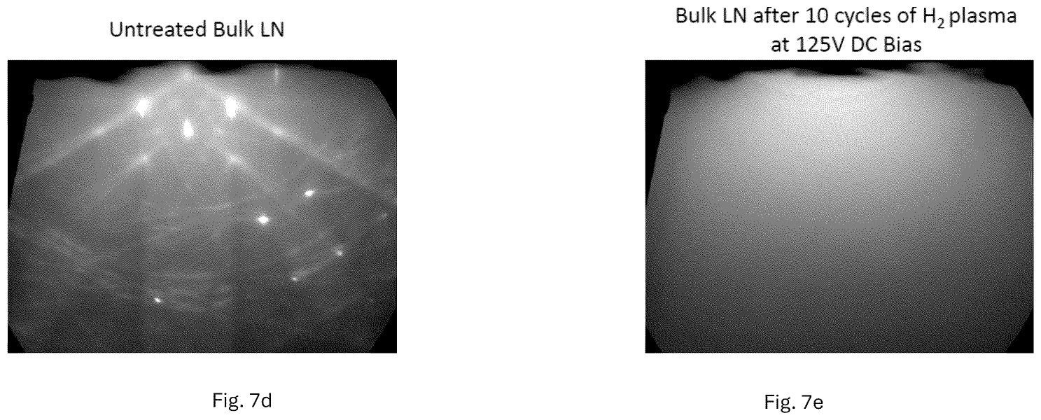

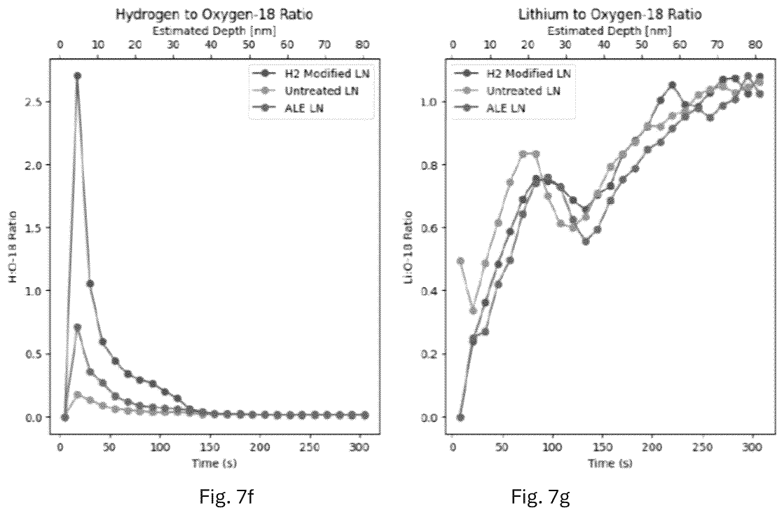

The line profile measurement in FIG. 7a shows rounded features, which suggests the hydrogen step may cause surface elevation by causing a phase transition from crystalline lithium niobate to an amorphous solid, which may be accompanied by expansion. Diffusion seems to interfere with anisotropy (the first two trenches are only visible in H₂ only profile).

Further chemical Analysis such as Depth Profile, XPS, SIMS for hydrogen detection and TEM can be performed to characterize the modified layer including its crystal structure. The RHEED diffraction data of FIG. 7b shows that exposure of LN substrate to H2 plasma amorphizes the crystalline surface, resulting to the volume increase of the crystal as observed in FIGS. 7a and 11a. FIG. 7c shows SIMS data after H₂ plasma exposure of the substrate for 3 minutes followed by ALE etching. The SIMS data confirms the presence of H₂ at the surface of the sample but no noticeable decrease in Li due the plasma exposure.

### 2. Removal

Removal of the modified layer using of small numbers of cycles of Fluorine/Chlorine was tested and the results are shown in FIG. 8. Modified samples that had been cleaned of photoresist were exposed to 3-6 cycles of fluorine/chlorine plasma and compared to control samples which still had photoresist. The results show both fluorine and chlorine can selectively etch modified regions

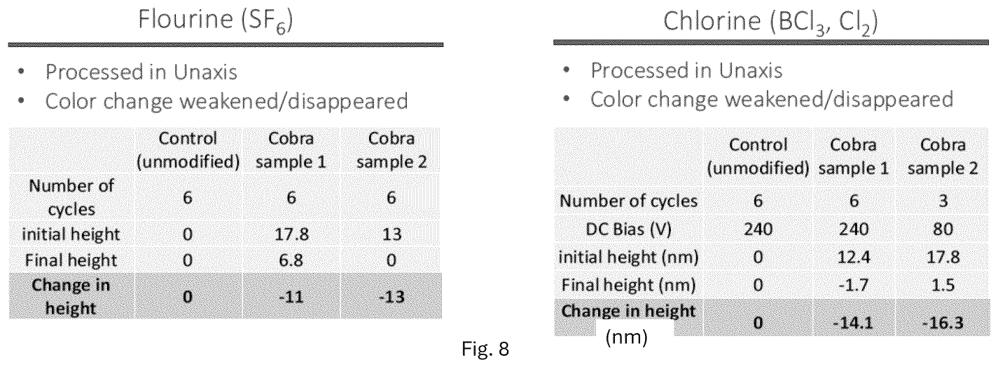

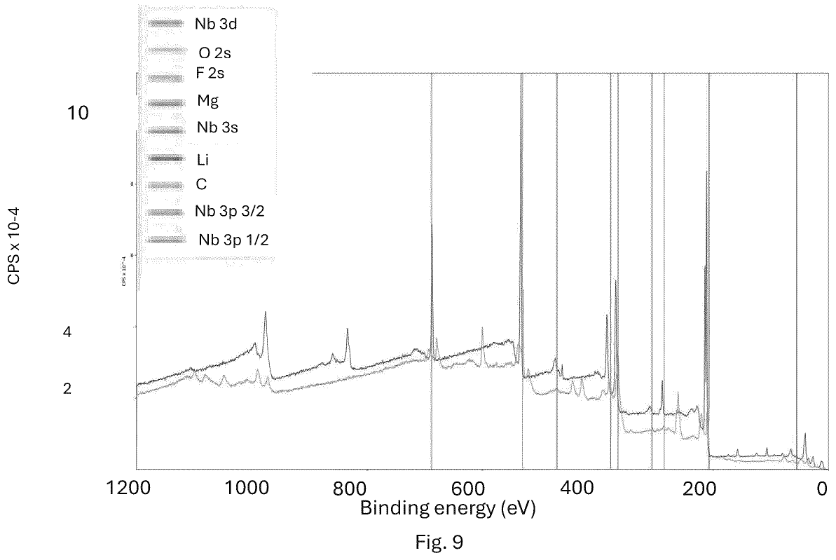

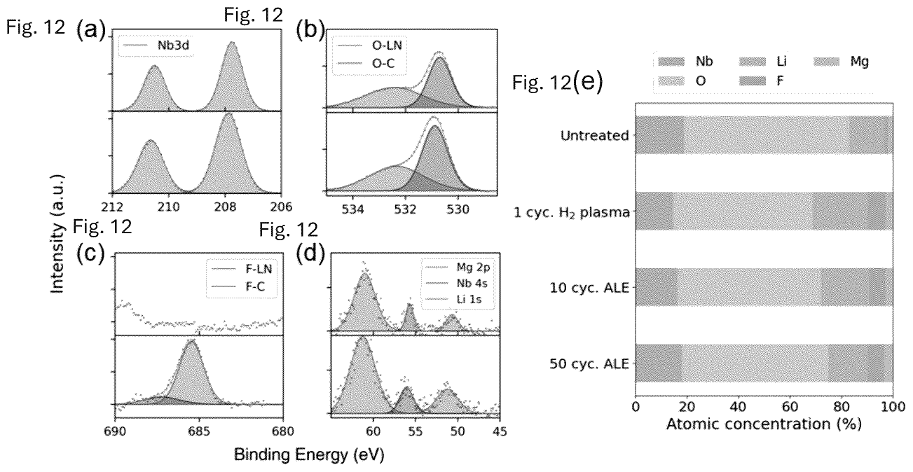

FIG. 9 shows Xray photoelectron spectroscopy scan of samples with surface modification (step 1) followed by treatment with fluorine in the form of SF6 (step 3). The sample exhibits a much stronger F peak after Fluorine dose. The XPS in FIG. 12 shows no lithium depletion was detected in the surface of the sample after one cycle of hydrogen plasma. The XPS shows that the ALE process forms LiF and MgF2 which are redeposited on the surface. A positive aspect of using ALE as described herein is that, unlike in the standard Ar+ milling process, it is possible to remove the redeposition of LiF and MgF2 selectively without etching the underlying waveguide structure.

### 3. ALE Etched Structure and Surface Roughness

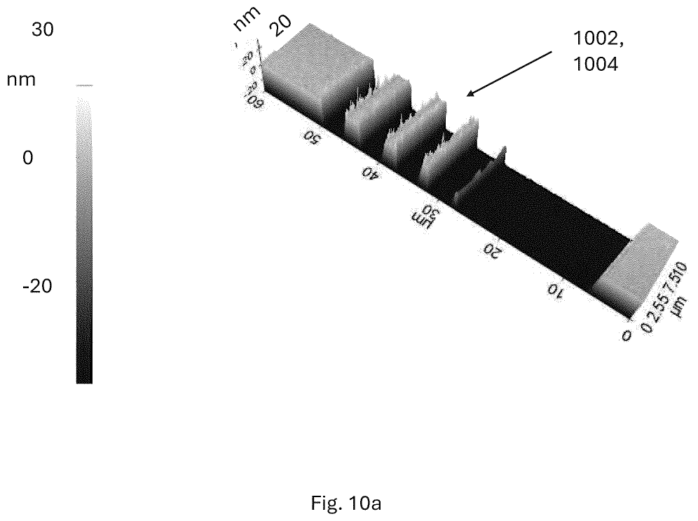

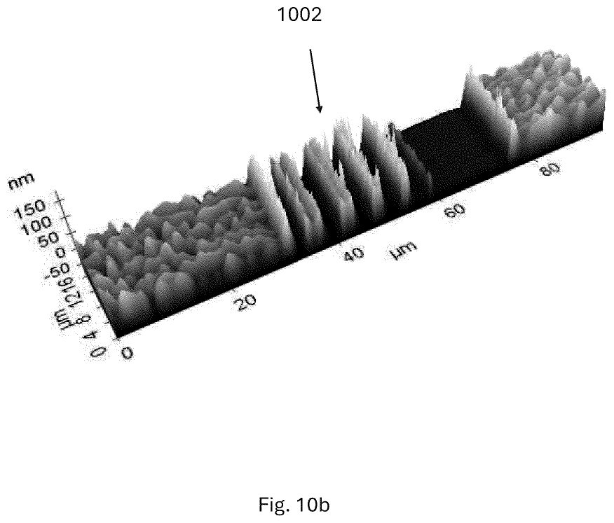

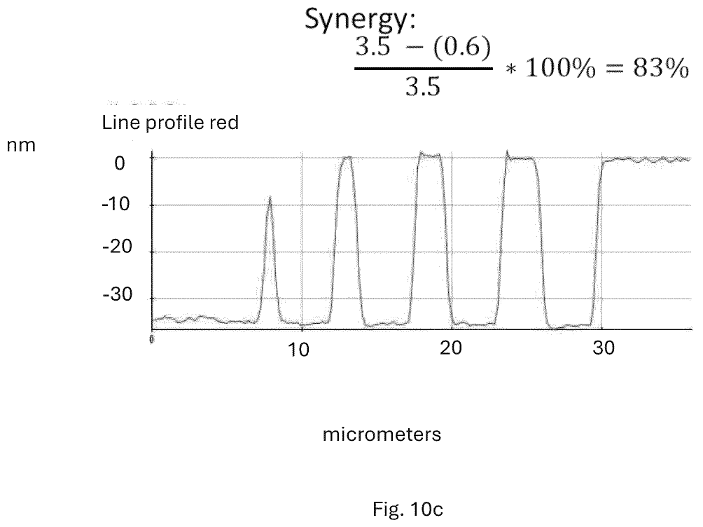

FIG. 10 is an AFM of the substrate using by repeating each of the following super-cycles 10 times:

Step 1: 5 cycles of H₂ alternating with argon

Step 2: Purging

Step 3: 5 cycles SF₆

Step 4: purging.

The etched trenches are smoother than the unetched material and it was possible The etched trenches have a depth of 35 nm with a precision of around the EPC of 3.5 nm.

The data shows improved results as compared to lithium niobate etched using chemical dry etch or by physical sputtering. RIE dry etch processes redeposit material like LiF that increase scattering loss-such redeposition was not observed in the ALE samples. Conventional argon milling still results in a rough etch depth controllable up to ±20 nm. The results using ALE show a much smoother surface (at least 30% smoother) with higher precision surface roughness as compared to the argon milling surfaces.

Possible modifications to the process include decreasing or increasing the number of super-cycles (e.g., up to 50) without removing all the photoresist, using a chlorine super-cycle (an optimized etch with chlorine has the potential to provide a smoother etch than fluorine with volatile etch products, current capability is characterized as shown in Table 3), using lower bias during the formation of the modified layer to increase synergy, using H₂ only during the formation of the modified layer, and modifying (e.g., lowering) temperature and/or pressure (e.g., lower) to control (e.g., increase) anisotropy of the etching.

The quality of the etch can also be evaluated by measuring the Q factor of an optical ring resonator patterned using the ALE process.

### 4. Example Reactor

FIG. 1 illustrates an ALE apparatus or tool 100 comprising a source of a reactant gas 102 (e.g., hydrogen); and a plasma source 104 or a source of a first field (e.g., an inductively coupled plasma ((ICP) source comprising ICP tube 106 and ICP radio frequency (RF) generator 108) for ionizing the reactant gas to form a plasma for reacting with a surface of a substrate 110 (comprising lithium niobate) to form a modified layer on the substrate. The tool further comprises a source of a treatment 112 (e.g., gas comprising halogen such as chlorine or fluorine or bromine or iodine) for removing the modified layer; and a source of a second field 114 (e.g., RF generator 116 and electrode 118) for accelerating ions in the plasma or treatment towards the substrate; a reaction chamber 120; a temperature stage 122 for controlling a temperature of the substrate; and a vacuum pump 124 for controlling purging and pressure within the reaction chamber.

The tool further comprises a computer 126 comprising a non-transitory computer readable medium storing a plurality of instructions for controlling the atomic layer etching using the tool. The plurality of instructions comprise outputting the reactant in a first cycle to form the modified layer, outputting the treatment to remove the modified layer in a second cycle so as to etch and/or smooth features in the lithium niobate; controlling the number of cycles, the temperature, pressure, an energy of the plasma or the ions incident on the substrate; and a dose of the reactant and the treatment.

### 5. Example Devices

The present disclosure reports on the first demonstration of an ALE type process that can chemically smoothen non-linear materials such as Lithium Niobate.

Example Thin Film Lithium Niobate (TLFN) devices that can be fabricated using the ALE process include integrated photonic circuits utilizing second order nonlinearity of the lithium niobate to manipulate electromagnetic radiation (e.g., optical pulses) for applications in optical computing, sensing, communication (use of MIR rather than NIR to minimize atmospheric absorption) for terrestrial and space applications (e.g., exoplanet detection), broadband spectroscopy, and frequency combs (e.g., that are wavelength standards for radial velocity measurements). Example structures that can be processed using ALE as described herein include waveguides and resonators.

### Additional Results

### 1. Experimental Methods

The samples consisted of bulk 3-inch 5% mol MgO-doped LN wafers (G&H Photonics). The wafers were diced into 7 mm×7 mm substrates using a Disco DAD 321 dicing saw and then cleaned by sonication in AZ NMP Rinse, acetone, and isopropyl alcohol. The samples were etched in an Oxford Instruments PlasmaPro 100 Cobra system configured for ALE. As shown in FIGS. 1(A) to 1(D), the process consisted of sequential exposures to H₂ and SF₆/Ar plasmas with purges between each exposure. This process was motivated by the observation that proton-exchanged LN can be etched with fluorine plasmas with reduced LiF redeposition [13,18,31-33] and because the same plasmas successfully achieved quasi-ALE of SiN. [58]

The nominal ALE recipe consists of an 40-second H₂ plasma exposure (300 W ICP power, 52.5 W RIE power, 209 V DC bias, 50 sccmH₂) followed by a 40-second SF₆/Ar exposure (300 W ICP power, 3.5 W RIE power, 50 V DC bias, 17 sccmSF₆, 35 sccmAr). The effect of EPC on RF bias power was not studied. 5 second purge times with 40 sccm Ar were used between plasma half-steps. The chamber pressure was set at 10 mTorr and the substrate table was cooled to 0° C. using liquid nitrogen as measured by the table thermometer.

To measure saturation curves, the chamber pressure and ICP power were kept constant at 10 m Torr and 300 W, respectively, during half-steps, while the exposure time for each half-step was varied. H₂ plasma exposure time was varied from 0 to 50 seconds with SF₆/Ar plasma held at 30 seconds, and SF₆/Ar plasma exposure time was varied from 0 to 50 seconds with H₂ plasma exposure held at 30 seconds. Prior to introducing the sample into the chamber for etching, the etching chamber was cleaned with a blank Si wafer and a 30 minute Ar⁺ plasma with 1500 W ICP and 100 W RF power followed by a 15-minute O₂/SF₆ plasma with the same power parameters. After the sample was loaded into the chamber, a 3-minute wait time was used before processing to allow the sample to thermally equilibrate with the table. All samples were etched for 50 cycles unless otherwise noted. After etching, the photoresist was removed using room temperature AZ NMP Rinse for at least 30 minutes to ensure complete removal of the resist, followed by sonication in acetone and isopropyl alcohol.

To enable etch depth measurements, step patterns consisting of periodic 400×400 μm² squares were written into a resist using photolithography, as shown in FIG. 4. The pattern was transferred to the +x face of the samples using AZ5214 photoresist and a Heidelberg MLA 150 Maskless Aligner with a dose of 150 mJ/cm², followed by development with AZ 300 MIF developer. Etch per cycle (EPC) was calculated by measuring the difference in height from etch depth for a processed sample and dividing it by the total number of cycles. AFM scans were performed on a Bruker Dimension Icon atomic force microscope (AFM) to measure total etch depth and surface roughness. The total etch depth was measured using 2.5×10 μm² AFM scan with the scan rate set to 0.5 Hz. The step profile was averaged over the entire scan using Nanoscope Analysis 1.9 software to obtain the etch depth. RMS surface roughness of a reference TFLNAr⁺ milled waveguide sample and power spectral density (PSD) scans were obtained over a 50×50 nm² area with a 0.5 Hz scan rate. Waveguide sidewall slope on measured TFLN samples and sample tilt from all AFM scans were removed via quadratic plane fit.

X-ray photoelectron spectroscopy (XPS) analysis was performed using a Kratos Axis Ultra x-ray photoelectron spectrometer using a monochromatic AlKα source. A 1.69 nm thick layer of carbon, as measured by a quartz crystal monitor, was deposited using sputtering to reduce charging effects during scans (Leica EM ACE600 Carbon Evaporator). The resulting data was analyzed in CASA-XPS from Casa Software Ltd. For each sample, we collected the carbon C1s, oxygen O1s, niobium Nb3d5/2 and Nb3d3/2, niobium Nb4s, lithium Li1s, fluorine F1s, and magnesium Mg2p peaks. The carbon C1s peak was used as a reference to calibrate peak positions. We fit the data using a Shirley background subtraction and peak fitting routines from Refs. [66, 67].

Two alternate recipes were also investigated. The first alternate recipe consists of a 40-second H₂ plasma exposure of the same parameters as the SF₆/Ar recipe followed by a 40-second O₂/SF₆ exposure (300 W ICP power, 3.5 W RIE power, 39 V DC bias, 35 sccmO₂,15 sccmSF₆). The second alternate recipe uses the same 40-second H₂ plasma exposure followed by a 40-second Cl₂/BCl₃ exposure (300 W ICP power, 5 W RIE power, 73 V DC bias, 20 sccmCl₂, 40 sccmBCl₃). The second alternate recipe was motivated by reports of ALE processes for metal oxides based on BCl₃, [42] and the Cl₂: BCl₃ gas flow ratio was selected based on an RIE recipe of LN using chlorine. [30] Whether the O₂/SF₆ and Cl₂/BCl₃ processes were at saturation was not determined. Etch depth measurements and 500×500 nm² surface roughness scans over 20 cycles from these alternate processes were compared with 20 cycles of the original ALE recipe consisting of a 40-second H₂ plasma exposure followed by a 40-second SF₆/Ar exposure.

### 2. Results

FIG. 11(A) shows the thickness change of LN versus cycle number for individual half cycles and the overall process. An etch rate of 0.06 nm/cycle is observed for the SF₆/Ar plasma half step. For the H₂ plasma step, a thickness increase was observed, which might be attributed to a volume expansion due to amorphization of the crystal during the H₂ plasma exposure. Such thickness increases for one half-step have been reported in other processes. [38] On the other hand, when using both steps sequentially, an etch rate of 1.59±0.02 nm/cycle is observed.

To gain more insight into the process and verify its self-limiting nature, we measured saturation curves for each half-cycle. In FIG. 11(B), the SF₆/Ar plasma half step is held constant at 30 seconds while the H₂ plasma exposure time is varied from 0 to 50 seconds. Saturation occurs at 1.46±0.04 nm/cycle above 30 seconds H₂ plasma exposure time.

In FIG. 11(C), the H₂ plasma exposure time is held constant at 30 seconds while the SF₆/Ar plasma exposure time is varied from 0 to 50 seconds. The etch rate exhibits a soft saturation, as the etch rate continues to increase with increasing exposure time. For SF₆/Ar exposure times longer than 30 seconds, the etch rate continues to increase at a rate of 0.1 nm/cycle per 10 seconds of additional SF₆/Ar plasma exposure, indicating that the half step exhibits soft saturation. Soft saturation with SF₆/Ar plasma has been reported previously and was attributed to the diffusion-limited fluorination of the surface [68]. In the present case, soft saturation is hypothesized to occur due to the presence of a concentration gradient of hydrogen into the LN film after H₂ plasma exposure. By increasing the SF₆/Ar plasma exposure time, more of the hydrogenated surface is removed, resulting in a soft-saturating curve. At 50 seconds SF₆ plasma exposure time, the etch rate is 1.59±0.02 nm/cycle. The observation of saturation for both half-steps indicates that the process is indeed atomic layer etching.

The synergy, S, as defined by Ref. [61], quantitatively compares the etch depth using only individual steps of the ALE cycle to the etching obtained with the full etch cycle as S=(1−(α+β)/EPC)×100, where α and β are the etch rate of the H₂ plasma and SF₆/Ar half-cycles, respectively; and EPC is the etch rate of the full cycle. For the present process in which a thickness increase is observed after H₂ plasma exposure, the synergy was calculated using a conservative approach assuming zero EPC for that step. We obtain a synergy value of 96.9% for the nominal recipe. This synergy value is comparable with typical synergy values reported in Ref. [37].

We also investigated alternate ALE recipes using O₂/SF₆ or Cl₂/BCl₃ plasma exposures for the removal step. The O₂/SF₆ ALE process yielded an etch rate of 2.24±0.01 nm/cycle over 20 cycles. The half-step EPCs for the H₂ and O₂/SF₆ plasma step are −0.04 and 0.01 nm/cycle, respectively. The synergy for this process is 99.5%, with the H₂ plasma half step assumed to be 0 EPC for purposes of calculation as previously noted. The Cl₂/BCl₃ ALE process yielded an EPC of 1.65±0.03 nm/cycle over 20 cycles; the half-step EPCs for the H₂ and Cl₂/BCl₃ plasma step are −0.04 and 0.14 nm/cycle, respectively, and the synergy for this process is 91.5%. While the reaction mechanisms of the three processes were not studied here, the possible reactions are hypothesized to be fluorine or chlorine radicals forming volatile compounds such as NbF₅, NbOF₃, OF₂, NbOClₓ, and BOClₓ as occurs in RIE of LN[30,69].

We next characterized the chemical composition of bulk LN before and after 50 cycles ALE for the SF₆/Ar plasma process using XPS. No depth-profiling XPS is reported due to preferential sputtering of O over Nb with an Ar⁺ beam, [70] complicating the interpretation of the measurements. The C1s peak at 284.8 eV is used as a reference. Binding energy values are reported in Table I. In FIGS. 12(A) to 12(D), we show the core levels of Nb3d, O1s; F1s; and Nb4s, Li1s, and Mg2p, respectively. For the Nb3d XPS spectra in FIG. 12(A), we observe a single doublet peak consisting of a 3 d_{5/2} and 3 d_{3/2} subpeak corresponding to LN (207.7 eV and 210.5 eV). [71-73]. FIG. 12(B) shows the O1s spectra with two subpeaks at 530.7 and 532.4 eV, corresponding to metal oxide and O—C bonds, respectively. [74]. FIG. 12(C), shows the F1s spectra with two subpeaks at 685.5 eV and 687.2 eV corresponding to LiF and F-C bonds, respectively. [73, 74].

TABLE I
Atomic concentrations for the fitted XPS data.

| Sample | Nb (%) | O (%) | Li (%) | F(%) | Mg(%) |
|---|---|---|---|---|---|
| Untreated | 18.92 ± | 64.17 ± | 13.68 ± | 1.32 ± | 1.91 ± |
| | 0.22 | 0.76 | 1.17 | 0.56 | 0.18 |
| 1 half cycle | 14.69 ± | 54.14 ± | 21.17 ± | 7.29 ± | 2.72 ± |
| H2 plasma | 0.26 | 0.97 | 2.15 | 0.21 | 0.44 |
| 10 cycles | 16.40 ± | 55.64 ± | 18.79 ± | 6.38 ± | 2.79 ± |
| ALE | 0.22 | 0.76 | 1.62 | 0.19 | 0.32 |
| 50 cycles | 18.04 ± | 56.83 ± | 15.17 ± | 6.56 ± | 3.40 ± |
| ALE | 0.17 | 0.55 | 1.15 | 0.13 | 0.19 |

FIG. 12D shows the Nb4s, Li1s, and Mg2p spectra at 61.0 eV, 55.7 eV, and 50.7 eV, respectively (values are for bulk LN). [73, 74] The Li1s peak energy agrees well with reported binding energies for LiF (55.7±0.5 eV). [72,74] After ALE, we observed a 0.3 eV shift for the Nb4s and Li1s peaks, and a 0.6 eV shift for the Mg 2 p peaks towards higher binding energies, as expected if fluoride bond formation occurred. [74] There is also an increased concentration of Mg after ALE, suggesting that MgF₂ is also formed.

FIG. 12(E) shows the atomic concentrations of Nb, Li, Mg, O, and F obtained from the XPS data at various stages of the process. The atomic concentrations are normalized by the estimated carbon content for each sample, which is about 55% and is due to presence of the conductive carbon coating. The uncertainties for all atomic concentration numbers (including C) were estimated from the CasaXPS software using a Monte Carlo routine, and the carbon-normalized uncertainties are propagated by adding uncertainties in quadrature. Surface lithium content is observed to increase after 1H₂ plasma half-cycle. The presence of fluorine is likely from residual fluorine on the chamber walls after the chamber clean. This trend differs from that reported in studies in which surface lithium concentration was found to decrease after a high power (500-2000 W), high temperature (170° C.), hour-long H₂ plasma exposure, forming proton-exchanged LN (c.f. FIG. 4 in Ref [18]). These plasma conditions in Ref [18] are more similar in terms of substrate temperature and exposure time to acid-based proton exchange, possibly accounting for the difference. After ALE, the fraction of F, Li, and Mg increases compared to those of the untreated sample. Considering as well the peak energy shifts mentioned earlier, we hypothesize that LiF and MgF₂ are formed and redeposited on the surface owing to their low volatility.

We characterized the effect of all three ALE recipes on surface roughness of bulk LN samples. AFM scans over 500×500 nm² were obtained on bulk LN subjected to 20 cycles of ALE. Table II compares the EPC, surface roughness, and synergy of the three different recipes. For reference, the bulk LN samples have an initial surface roughness of R_{q}=0.2 nm. The O₂/SF₆ process yielded the roughest surface but the highest synergy, and the Cl₂/BCl₃ process yielded a similar etch rate to the SF₆/Ar process with the lowest synergy of the three recipes. It is hypothesized that the Cl₂/BCl₃ process may be modified to have higher synergy by lowering the RIE power on the Cl₂/BCl₃ plasma half step. In comparison, the SF₆/Ar process at saturation produced the smoothest surface after 20 cycles of ALE with R_{q} of 0.57±0.18 nm. The increase in surface roughness may be attributed to redeposition of LiF and MgF₂.

TABLE II
Comparison of metrics from LN ALE recipes with different removal
step plasma exposures on bulk LN. The bulk LN samples used have an
initial surface roughness of R_{q} = 0.2 nm. Values are from a 40
second H₂ plasma exposure followed by a 40 second plasma exposure
indicated in the table, over 20 cycles. Whether the O₂/SF₆ and
Cl₂/BCl₃ processes were at saturation was not determined.

| | | RMS | Average | |
|---|---|---|---|---|
| Plasma | EPC | Roughness | Roughness | Synergy |
| Type | (nm/cycle) | (nm) | (nm) | (%) |
| SF₆/Ar | 1.59 ± 0.02 | 0.57 ± 0.18 | 0.44 ± 0.11 | 96.9 |
| O₂/SF₆ | 2.24 ± 0.02 | 1.47 ± 0.52 | 0.99 ± 0.40 | 99.5 |
| Cl₂/BCl₃ | 1.65 ± 0.03 | 0.90 ± 0.46 | 0.59 ± 0.20 | 91.5 |

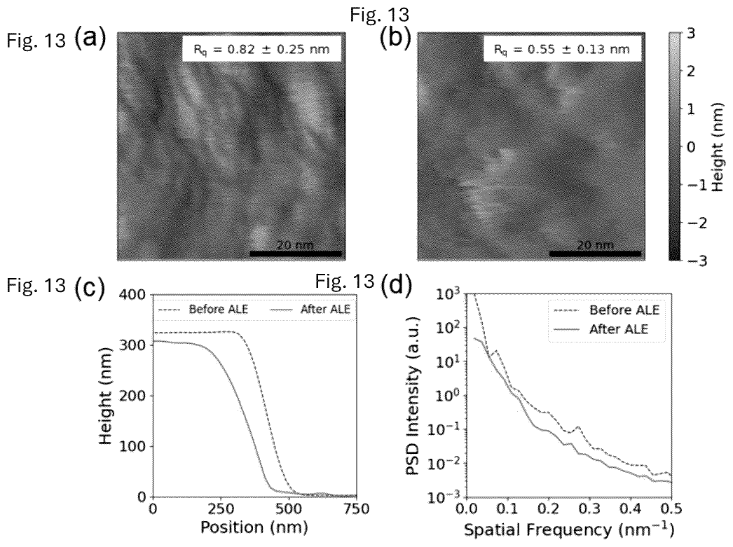

Since sidewall roughness of TFLN waveguides are rougher than the surface of bulk LN samples, we next characterized the effect of the SF₆/Ar ALE process on the sidewall surface roughness of TFLN waveguides. For these measurements, we used additional samples consisting of TFLN with Ar⁺ milled waveguides that were smoothed post-etch with an HF dip and RCA clean, corresponding to the state-of-art process for TFLN device fabrication. [11, 34] FIGS. 13(A) and 13(B) show the quadratic plane-fit height map of Ar⁺ etched sidewall before and after 50 cycles of ALE, respectively. After ALE, the sidewall surface is visually smoother. The sidewall surface smoothing may be attributed to the isotropic nature of the etch.

To support this hypothesis, we measured the lateral etch rate of the waveguide using AFM. FIG. 13(C) shows an AFM profile averaged over the whole scanned image of the TFLN waveguide sidewall before and after 50 cycles of ALE. From the decrease in width, we infer the lateral etch rate to be 1 nm/cycle on each side of the waveguide compared to a vertical etch rate of 1.59 nm/cycle previously measured on bulk LN, confirming the largely isotropic nature of the process.

To more quantitatively characterize the surface topology of the TFLN sidewalls, we computed the surface power spectral density (PSD) from the AFM scans. FIG. 13(D) shows the PSD curves before and after ALE on TFLN. Using AFM scans, the initial RMS sidewall roughness is measured to be 1.29±0.20 nm and an average roughness of 1.05±0.19 nm. After 50 cycles, R_{q} and Rₐ are measured as 0.55±0.13 nm and 0.44±0.12 nm, respectively. The PSD is observed to decrease over all measured spatial frequencies. Therefore, despite the roughening observed on flat LN surfaces, sidewall smoothing is still observed owing to the isotropic nature of the process.

### 3. Discussion

The data presented herein shows the ALE process may find applications in improving the photonic performance of TFLN devices by reducing optical loss associated with corrugations in PPLN and sidewall roughness. The etch rate of a typical RCA wet etch exhibits uncontrolled variability due to temperature and concentration fluctuations in solution. The reported ALE process here has potential to overcome these issues due to the self-limiting nature of the process with well-controlled etch rates.

The mechanism for etch selectivity of the hydrogen-exposed surface over the unmodified surface can be investigated and approaches to reduce the quantity of redeposited Li and Mg compounds can be identified. A post-ALE wet clean may be beneficial to remove the redeposited compounds selectively, in contrast to the present approach using an RCA wet etch which etches lithium niobate. Development of an in-situ gas-based removal process or a process based on thermal cycling may enable redeposition-free ALE. For thermally cyclic processing, investigation of chemistries which produce more volatile products, such as those based on Br, is of interest for further study. Directional ALE processes with high anisotropy are also of interest as they could be employed for pattern transfer, yielding precise and uniform control of etch depth over the entire chip with precision of around the EPC (˜1 nm). This degree of control would permit scaling of TFLN devices and circuits to the system level. The ALE system herein (Oxford Instruments, Plasma Pro 100 Cobra) is able to process 150 mm diameter substrates, and therefore our process has the potential to extend to wafer-scale applications.

The present disclosure described an isotropic ALE process for x-cut MgO-doped lithium niobate consisting of sequential exposures of hydrogen plasma and SF₆/Ar plasma that is compatible with low-pressure ICP RIE systems. We observe an etch rate of 1.59±0.02 Å/cycle with a synergy exceeding 96%. Both half-steps exhibited saturation with respect to exposure time, though the SF₆ plasma half step was observed to soft-saturate. The substitution of O₂/SF₆ or Cl₂/BCl₃ plasmas in place of SF₆/Ar plasma was also found to yield ALE with synergies exceeding 90%. Finally, the process was found to smoothen the sidewalls of TFLN waveguides fabricated using the state-of-art process, suggesting the potential of ALE to enhance the photonic performance of TFLN devices.

### Process Steps

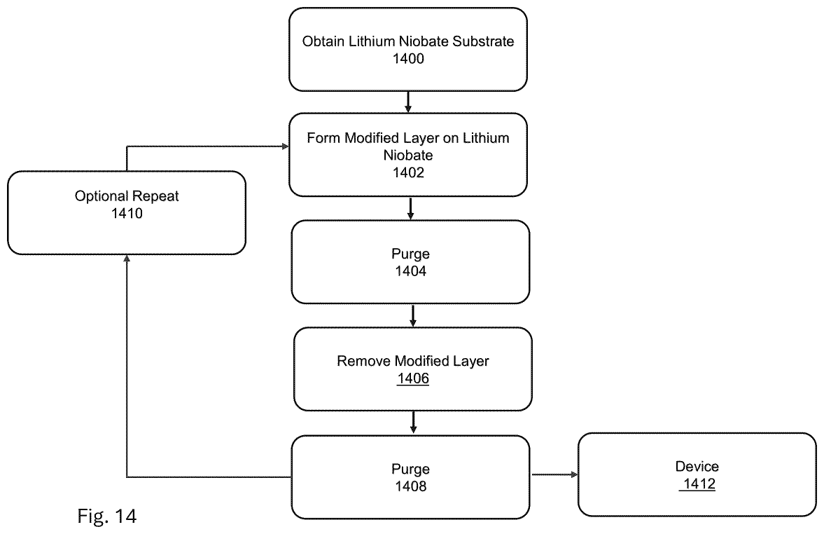

FIG. 14 illustrates a method of etching lithium niobate, comprising etching a substrate comprising lithium niobate using atomic layer etching.

The method can comprise the following steps.

Block 1400 represents obtaining the substrate comprising lithium niobate, e.g., covered with a patterned resist layer exposing regions of the lithium niobate to be etched.

Block 1402 represents exposing the lithium niobate to a reactant that combines with the lithium niobate to form a compound in a modified layer. In one embodiment, the step comprises bombarding or exposing the lithium niobate with/to a hydrogen plasma comprising protons accelerated by a bias in an ALE reactor, to form a modified layer on the lithium niobate substrate;

Block 1404 represents optionally purging the reactor using an inert gas (e.g., argon).

Block 1406 represents at least partially removing the modified layer using a removal agent, wherein the modified layer is removed at a higher rate than the lithium niobate. In one embodiment, the removing comprises sputtering at low power using chemical species or using ions accelerated by a bias. In another embodiment, the removing comprises exposing the modified layer to the removal agent comprising chlorine or fluorine as a neutral species or in a plasma as an ionic species accelerated by a bias.

Block 1408 represents optionally purging the reactor using an inert gas (e.g., argon).

Block 1410 represents optionally repeating steps 1402-1408.

Block 1412 represents the end result, a device.

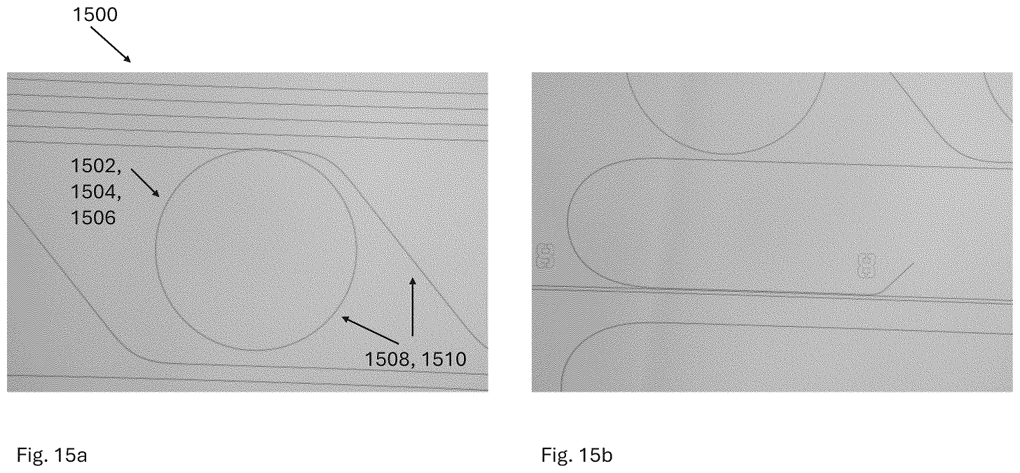

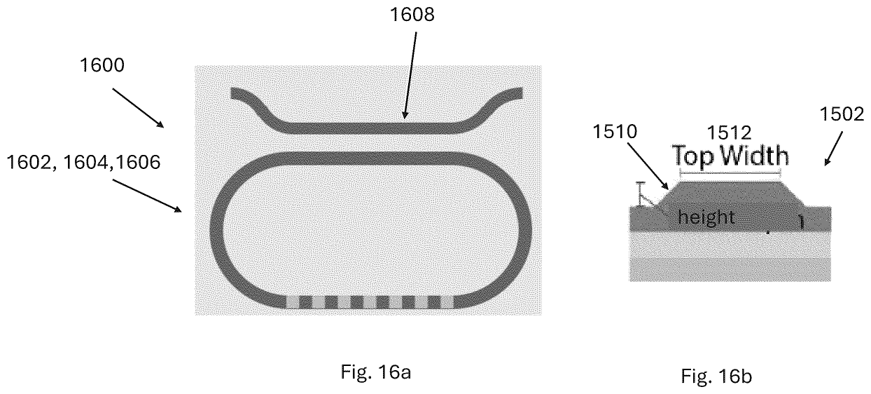

Illustrative embodiments of the method, device manufactured using the method, the apparatus used to implement the method include, but are not limited to, the following (referring to FIGS. 1-15).

1. A device 1600 comprising:
a structure 1602, 1002 (e.g., waveguide 1604 or resonator 1606) patterned into a lithium niobate substrate using atomic layer etching, or
a structure 1502, 1002 (e.g., waveguide 1504 or resonator 1506) comprising lithium niobate having a surface 1508, 1004 (e.g., of a sidewall 1510, an inclined sidewall (e.g., more than 30 degrees), or cross-section or top surface 1512) smoothened using atomic layer etching.

2. The device of clause 1, wherein the surface comprises hydrogen, an amorphized layer of the lithium niobate, and a surface roughness less than 3.5 nm.

3. A device 1600 comprising a structure 1602, 1002 patterned into a lithium niobate, wherein a surface 1608, 1004 of the lithium niobate comprises at least one of hydrogen, an amorphized or amorphous layer, or a surface roughness less than 3.5 nm or less than 1.5 nm.

4. The device of any of the clauses 1-3, wherein the surface is an x-cut surface optionally comprising magnesium oxide.

5. A method of etching lithium niobate, comprising:
etching a substrate comprising lithium niobate using atomic layer etching, wherein the etching comprises patterning a photonic integrated circuit or one or more device structures in the lithium niobate and/or smoothing the surface of one or more device structures that have been patterned by another process.

6. The method of clause 5, further comprising:
obtaining the substrate covered with a patterned resist layer exposing regions of the lithium niobate to be etched; and etching the exposed regions using the atomic layer etching.

7. The method of any of the clauses 5-6, wherein the etching comprises:
(a) bombarding the lithium niobate with a hydrogen plasma comprising protons accelerated by a bias in an ALE reactor, to form a modified layer on the lithium niobate substrate;
(b) purging the reactor using an inert gas;
(c) removing the modified layer using a removal agent; and
(d) purging the reactor using an inert gas.

8. The method of any of the clauses 5-7, wherein the etching comprises:
(c) exposing the lithium niobate to a reactant that combines with the lithium niobate to form a compound;
(d) optionally purging the reactor using an inert gas;
(c) removing the modified layer using a removal agent, wherein the modified layer is removed at a higher rate than the lithium niobate; and
(d) optionally purging the reactor using an inert gas.

9. The method of clause 7 or 8, wherein the removing comprises sputtering using chemical species or using ions accelerated by a bias under conditions that remove the modified layer over the bulk lithium niobate in a self-limiting process.

10. The method of clause 7 or 8, wherein the removing comprises sputtering at low power using chemical species or using ions accelerated by a bias wherein a preferred range would be <15 W RIE power, or a measured DC bias of <60V.

11. The method of any of the clauses 9-10, wherein the removing comprises exposing the modified layer to the removal agent comprising chlorine or fluorine as a neutral species or in a plasma as an ionic species accelerated by a bias.

12. The method of any of the clauses 7-11, wherein the inert gas comprises argon.

13. The method of any of the clauses 7-12, further comprising performing multiple cycles of step (a) and (b) prior to performing step (c).

14. The method of any of the clauses 7-13, further comprising performing multiple cycles of step (a) and (c), wherein the bias ranges range from 0V DC bias to 60V DC bias and observed etch rates are <1 nm/cycle to >3 nm/cycle.

15. The method or device of any of the clauses, wherein the etched surface is etched with nanometer resolution (or with a surface roughness less than 3.5 nm, less than 2 nm, less than 1.5 nm, or less than 1 nm, and/or the etched surface is smoother than the non etched regions).

16. The method of any of the clauses 5-15, further comprising one or more cycles of:
(a) exposure of the substrate to a dose of the hydrogen plasma for a duration and under a bias and temperature and pressure such that the hydrogen adsorbs on a surface of the substrate in a self limiting process as characterized by the hydrogen saturating all available reactive bonding sites with the lithium niobate to form a modified layer; and
(b) exposure of the modified layer to a dose of the chemical species comprising a halogen (e.g., fluorine or chlorine or bromine) at a temperature, pressure and energy such that the chemical species selectively removes the modified layer over the underlying bulk lithium niobate in a self-limiting process; and
such that (e.g., a synergy of the atomic layer etching resulting from the cycles is at least 80% or 90% or 95%) and/or removal of one or more atomic layers of the lithium niobate after each cycle can be controlled with precision of a single one of the atomic layers.

17. The method or device of any of the clauses 1-16, wherein the photonic integrated circuit or device structure includes at least one of a waveguide or resonator (e.g., less than 5 micron wide and 1 micron deep).

18. The method or device of any of the clauses 1-17, wherein the ALE is performed on an x-cut surface of the lithium niobate.

19. The method of any of the any of the clauses 5-17, further comprising controlling an angle of incidence or angular distribution of the removal agent on the substrate by controlling at least one of the temperature or pressure or bias, so as to control anisotropy and/or inclination of the etched surface and crystal quality of the etched lithium niobate.

20. The method of any of the clauses 5-19, wherein the removing comprises a selective process that removes redeposited species (such as Li, Mg) without etching the lithium niobate in the substrate.

21. The method of clause 20, wherein the removing comprises thermal cycling or wet etching using a liquid removal agent.

22. The method of any of the clauses 5-21, further comprising selecting an angle of incidence or angular distribution of the reactant/and or removal agent on the substrate to etch and/or smoothen sidewalls of a waveguide or structure comprising the lithium niobate.

23. The method of any of the clauses 5-22, wherein the removal agent comprises SF6/argon.

24. An atomic layer etching apparatus:
An atomic layer reactor (e.g., comprising a reactor a source of a reactant for reacting with a surface of a substrate so as to form a modified layer on the substrate, wherein the reactant is generated by a plasma, and the substrate comprises lithium niobate; a source of a treatment for removing the modified layer; and a computer comprising a non-transitory computer readable medium storing a plurality of instructions, the plurality of instructions comprising outputting the reactant in the reactor tool, outputting the treatment to remove the modified layer so as to etch and/or smooth features in the lithium niobate.

25. The reactor of clause 24 performing the method of any of the clauses 5-23.

26. A device manufactured using the method or apparatus of any of the clauses 5-25.

27. The ALE apparatus of any of the clauses 24-26, wherein the computer comprises a computer-implemented system, comprising:
(a) a computer having a memory;
(b) a processor executing on the computer;
(c) the memory storing a set of instructions, wherein the set of instructions, when executed by the processor cause the processor to perform operations comprising instructing the apparatus to perform the method steps of any of the clauses 5-27 such as, but not limited to, outputting the reactant and removal agent under appropriate conditions and for an appropriate number of cycles.

### Advantages and Improvements

Lithium niobate (LiNbO₃ or LN) is a ferroelectric crystal of interest for a variety of integrated photonics applications ranging from electro-optic modulators in fiber-optic communications to quantum optics. [1] LN is a trigonal crystal characterized by a threefold rotational symmetry about the crystallographic z axis. Because x-cut electro-optic modulators have fewer processing requirements compared to their z-cut counterparts, [2] the x-cut surface is the relevant surface for LN nanophotonic circuits. The crystal structure of LN is described in Refs. [3-5]. LN exhibits a number of desirable properties for photonics, including a large transparency window, wide electro-optic bandwidth, ferroelectric properties, and high second-order nonlinear susceptibility, [6-10] making it an attractive platform compared to other materials like silicon nitride. [11] By incorporating >5% molar concentration MgO into the melt during the Czochralski crystal growth process, the optical damage threshold is raised, allowing for high-intensity photonic applications [12].
Early efforts to create on-chip photonic devices involved Ti ion diffusion or proton exchange on bulk LN wafers to provide the necessary refractive index contrast. [13-18]. However, the relatively small refractive index contrast from this approach resulted in weak optical confinement, imposing limitations on the types of devices and nonlinear phenomena that could be observed. With the development of ion-slicing and wafer bonding processes for LN on silicon dioxide, [19-21]thin-film lithium niobate (TFLN) wafers have become commercially available, allowing for the realization of dense circuits with tightly-confining waveguides. Devices that have been fabricated on TFLN include squeezed quantum states on-chip, [22]>100 GHz electro-optic modulators with CMOS compatible voltages, [23] broadband frequency comb sources, [24-26] and on-chip ultra-fast lasers. [27, 28].
A necessary step in LN device fabrication is pattern transfer, typically using a dry etching process. Process development for dry etching of LN is more challenging compared to that for other photonic materials such as SiN because LN is a ternary compound. Fluorine-[29] or chlorine- [30] based reactive ion etching (RIE) processes have been reported, but they suffer from redeposition of non-volatile Li compounds such as LiF, leading to an increase in sidewall roughness and scattering loss, which is the dominant loss mechanism. [11, 29] Proton exchanged LN has been noted to have lower LiF redeposition during plasma etching due to lower surface Li content. Deep (>1 μm) fluorine-based etches with less LiF redeposition have been accomplished with proton-exchanged LN. [13, 31-33].
In the device community, physical Ar⁺ milling remains the preferred dry etch method used for pattern transfer. However, this method has its own limitations such as low etch selectivity with common lithography resists, non-vertical sidewalls, redeposition of LN, and variations of etch depth across a single chip. [11, 34] Various approaches are available to remedy some of these limitations; for instance, redeposited LN after Ar⁺ milling is typically removed using an RCA clean. However, the wet process also introduces micron-sized corrugations in periodically-poled LN (PPLN) due to differential wet etch rates between poled domains, [35] leading to optical loss which dominates the overall loss in TFLN devices. [36] As a result, various device figures of merit such as resonator quality factors are at least an order of magnitude from their intrinsic upper limits. Decreasing losses associated with corrugations and sidewall roughness in PPLN circuits will enable system-level integration of on-chip nonlinear optics and allow for quantum information processing. [11].
These challenges could be addressed with improved nanofabrication techniques which offer sub-nanometer-scale etch depth control and surface smoothing. In particular, thermal or plasma-enhanced atomic layer etching (ALE) has demonstrated etch depth control on the angstrom scale and an ability to smooth surfaces to the sub-nanometer scale. [37, 38] ALE consists of sequential, self-limiting surface chemical processes that lead to etch per cycles ranging from fractional monolayers to a few monolayers in crystalline materials. ALE can be anisotropic (directional) or isotropic (thermal or plasma-thermal). [38-40] Anisotropic ALE is based on surface modification by adsorption of a reactant followed by low-energy ion or neutral atom sputtering. [39, 41, 42] The self-limiting nature of anisotropic ALE is defined by the thickness of the modified surface and the difference in sputtering threshold between the modified and unmodified surface. Thermal (isotropic) ALE is based on a cycle of surface modification and volatilization reactions. Recent developments in ALE have also employed a pulsed-bias approach, where the flow of gases is held constant and the DC bias is turned on and off, resulting in faster ALE cycle times. [43] Thermal and anisotropic ALE recipes have been developed for various semiconductors and dielectrics such as SiO₂, [44, 45] InP, [46-48] GaAs, [49-52] and Si₃ N₄. [53-58] Surface smoothing due to ALE has been observed for various materials, [37, 58-64] a feature which has been attributed to conformal layer-by layer removal and curvature-dependent surface modification. [65] Despite the potential to smooth step pattern corrugations and sidewall roughness in PPLN, no ALE processes have been reported for LN until now. In one embodiment of the present invention, an anisotropic quasi-ALE process for x-cut MgO-doped LN was successfully implemented using sequential exposures of H₂ and SF6 plasma. For this recipe, we observed etch rates up to 2.1 nm/cycle with a synergy of ˜97% and characterized the etched surfaces using X-ray photoelectron spectroscopy, secondary-ion mass spectrometry, and atomic force microscopy. The results show this process can be used as a post-processing step to smooth patterned TFLN surfaces which may both increase the performance of existing TFLN devices and enable novel devices not attainable in other integrated photonic platforms.

### Hardware Environment

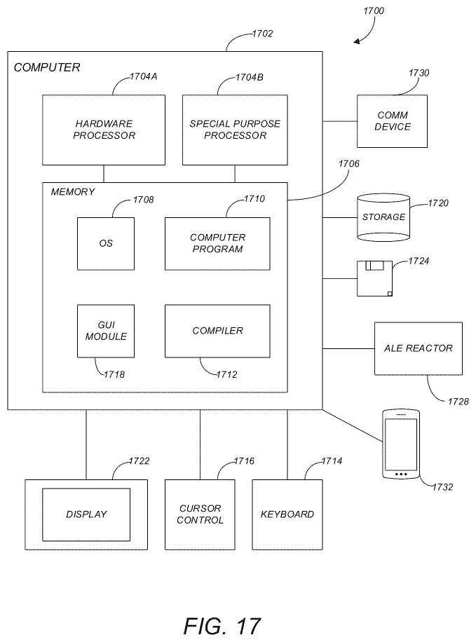

FIG. 17 is an exemplary hardware and software environment 1700 (referred to as a computer-implemented system and/or computer-implemented method) used to implement one or more embodiments of the invention. The hardware and software environment includes a computer 1702 and may include peripherals. Computer 1702 may be a user/client computer, server computer, or may be a database computer. The computer 1702 comprises a hardware processor 1704A and/or a special purpose hardware processor 1704B (hereinafter alternatively collectively referred to as processor 1704) and a memory 1706, such as random access memory (RAM). The computer 1702 may be coupled to, and/or integrated with, other devices, including input/output (I/O) devices such as a keyboard 1714, a cursor control device 1716 (e.g., a mouse, a pointing device, pen and tablet, touch screen, multi-touch device, etc.) and a printer 1728. In one or more embodiments, computer 1702 may be coupled to, or may comprise, a portable or media viewing/listening device 1732 (e.g., an MP3 player, IPOD, NOOK, portable digital video player, cellular device, personal digital assistant, etc.). In yet another embodiment, the computer 1702 may comprise a multi-touch device, mobile phone, gaming system, internet enabled television, television set top box, or other internet enabled device executing on various platforms and operating systems.

In one embodiment, the computer 1702 operates by the hardware processor 1704A performing instructions defined by the computer program 1710 (e.g., a computer-controlled ALE application) under control of an operating system 1708. The computer program 1710 and/or the operating system 1708 may be stored in the memory 1706 and may interface with the user and/or other devices to accept input and commands and, based on such input and commands and the instructions defined by the computer program 1710 and operating system 1708, to provide output and results.

Output/results may be presented on the display 1722 or provided to another device for presentation or further processing or action. In one embodiment, the display 1722 comprises a liquid crystal display (LCD) having a plurality of separately addressable liquid crystals. Alternatively, the display 1722 may comprise a light emitting diode (LED) display having clusters of red, green and blue diodes driven together to form full-color pixels. Each liquid crystal or pixel of the display 1722 changes to an opaque or translucent state to form a part of the image on the display in response to the data or information generated by the processor 1704 from the application of the instructions of the computer program 1710 and/or operating system 1708 to the input and commands. The image may be provided through a graphical user interface (GUI) module 1718. Although the GUI module 1718 is depicted as a separate module, the instructions performing the GUI functions can be resident or distributed in the operating system 1708, the computer program 1710, or implemented with special purpose memory and processors.

In one or more embodiments, the display 1722 is integrated with/into the computer 1702 and comprises a multi-touch device having a touch sensing surface (e.g., track pod or touch screen) with the ability to recognize the presence of two or more points of contact with the surface. Examples of multi-touch devices include mobile devices (e.g., IPHONE, NEXUS S, DROID devices, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 1702 according to the computer program 1710 instructions may be implemented in a special purpose processor 1704B. In this embodiment, some or all of the computer program 1710 instructions may be implemented via firmware instructions stored in a read only memory (ROM), a programmable read only memory (PROM) or flash memory within the special purpose processor 1704B or in memory 1706. The special purpose processor 1704B may also be hardwired through circuit design to perform some or all of the operations to implement the present invention. Further, the special purpose processor 1704B may be a hybrid processor, which includes dedicated circuitry for performing a subset of functions, and other circuits for performing more general functions such as responding to computer program 1710 instructions. In one embodiment, the special purpose processor 1704B is an application specific integrated circuit (ASIC), field programmable gate array.

The computer 1702 may also implement a compiler 1712 that allows an application or computer program 1710 written in a programming language such as C, C++, Assembly, SQL, PYTHON, PROLOG, MATLAB, RUBY, RAILS, HASKELL, or other language to be translated into processor 1704 readable code. Alternatively, the compiler 1712 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 1710 accesses and manipulates data accepted from I/O devices and stored in the memory 1706 of the computer 1702 using the relationships and logic that were generated using the compiler 1712.

The computer 1702 also optionally comprises an external communication device such as a modem, satellite link, Ethernet card, or other device for accepting input from, and providing output to, other computers 1702.

In one embodiment, instructions implementing the operating system 1708, the computer program 1710, and the compiler 1712 are tangibly embodied in a non-transitory computer-readable medium, e.g., data storage device 1720, which could include one or more fixed or removable data storage devices, such as a zip drive, floppy disc drive 1724, hard drive, CD-ROM drive, tape drive, etc. Further, the operating system 1708 and the computer program 1710 are comprised of computer program 1710 instructions which, when accessed, read and executed by the computer 1702, cause the computer 1702 to perform the steps necessary to implement and/or use the present invention or to load the program of instructions into a memory 1706, thus creating a special purpose data structure causing the computer 1702 to operate as a specially programmed computer executing the method steps described herein. Computer program 1710 and/or operating instructions may also be tangibly embodied in memory 1706 and/or data communications devices 1730, thereby making a computer program product or article of manufacture according to the invention. As such, the terms “article of manufacture,” “program storage device,” and “computer program product,” as used herein, are intended to encompass a computer program accessible from any computer readable device or media.

Of course, those skilled in the art will recognize that any combination of the above components, or any number of different components, peripherals, and other devices, may be used with the computer 1702.

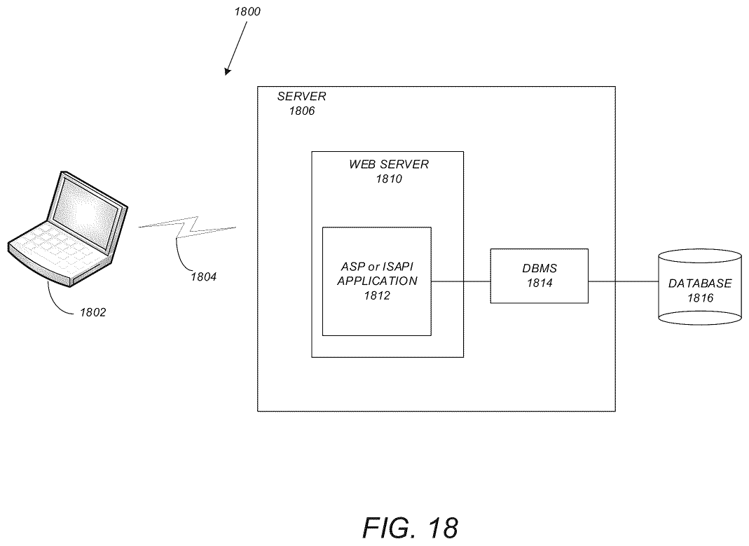

FIG. 18 schematically illustrates a typical distributed/cloud-based computer system 1800 using a network 1804 to connect client computers 1802 to server computers 1806. A typical combination of resources may include a network 1804 comprising the Internet, LANs (local area networks), WANs (wide area networks), SNA (systems network architecture) networks, or the like, clients 1802 that are personal computers or workstations (as set forth in FIG. 17), and servers 1806 that are personal computers, workstations, minicomputers, or mainframes (as set forth in FIG. 17). However, it may be noted that different networks such as a cellular network (e.g., GSM [global system for mobile communications] or otherwise), a satellite based network, or any other type of network may be used to connect clients 1802 and servers 1806 in accordance with embodiments of the invention.

A network 1804 such as the Internet connects clients 1802 to server computers 1806. Network 1804 may utilize ethernet, coaxial cable, wireless communications, radio frequency (RF), etc. to connect and provide the communication between clients 1802 and servers 1806. Further, in a cloud-based computing system, resources (e.g., storage, processors, applications, memory, infrastructure, etc.) in clients 1802 and server computers 1806 may be shared by clients 1802, server computers 1806, and users across one or more networks. Resources may be shared by multiple users and can be dynamically reallocated per demand. In this regard, cloud computing may be referred to as a model for enabling access to a shared pool of configurable computing resources.

Clients 1802 may execute a client application or web browser and communicate with server computers 1806 executing web servers 1810. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 1802 may be downloaded from server computer 1806 to client computers 1802 and installed as a plug-in or ACTIVEX control of a web browser. Accordingly, clients 1802 may utilize ACTIVEX components/component object model (COM) or distributed COM (DCOM) components to provide a user interface on a display of client 1802. The web server 1810 is typically a program such as MICROSOFT'S INTERNET INFORMATION SERVER.

Web server 1810 may host an Active Server Page (ASP) or Internet Server Application Programming Interface (ISAPI) application 1812, which may be executing scripts. The scripts invoke objects that execute business logic (referred to as business objects). The business objects then manipulate data in database 1816 through a database management system (DBMS) 1814. Alternatively, database 1816 may be part of, or connected directly to, client 1802 instead of communicating/obtaining the information from database 1816 across network 1804. When a developer encapsulates the business functionality into objects, the system may be referred to as a component object model (COM) system. Accordingly, the scripts executing on web server 1810 (and/or application 1812) invoke COM objects that implement the business logic. Further, server 1806 may utilize MICROSOFT'S TRANSACTION SERVER (MTS) to access required data stored in database 1816 via an interface such as ADO (Active Data Objects), OLE DB (Object Linking and Embedding DataBase), or ODBC (Open DataBase Connectivity).

Generally, these components 1800-1816 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 1802 and 1806 may be interchangeable and may further include thin client devices with limited or full processing capabilities, portable devices such as cell phones, notebook computers, pocket computers, multi-touch devices, and/or any other devices with suitable processing, communication, and input/output capability.

Of course, those skilled in the art will recognize that any combination of the above components, or any number of different components, peripherals, and other devices, may be used with computers 1802 and 1806. Embodiments of the invention are implemented as a software/ALE application on a client 1802 or server computer 1806. Further, as described above, the client 1802 or server computer 1806 may comprise a thin client device or a portable device that has a multi-touch-based display.

### REFERENCES

The following references are incorporated by reference herein.
[1] A. Boes, L. Chang, C. Langrock, M. Yu, M. Zhang, Q. Lin, M. Lončar, M. Fejer, J. Bowers, and A. Mitchell, Science 379, eabj4396 (2023).
[2]M. Zhang, C. Wang, P. Kharel, D. Zhu, and M. Lončar, Optica 8, 652 (2021).
[3]N. Iyi, K. Kitamura, Y. Yajima, S. Kimura, Y. Furukawa, and M. Sato, J. Solid State Chem. 118, 148 (1995).
[4]S. Sanna and W. G. Schmidt, J. Phys.: Condens. Matter 29, 413001 (2017), publisher: IOP Publishing.
[5]S. Sanna and W. G. Schmidt, Phys. Rev. B. 81, 214116 (2010).
[6]R. S. Weis and T. K. Gaylord, Appl. Phys. A 37, 191 (1985).
[7]K.-K. Wong, Properties of lithium niobate, 28 (IET, 2002).
[8]Y. Kong, F. Bo, W. Wang, D. Zheng, H. Liu, G. Zhang, R. Rupp, and J. Xu, Adv. Mater. 32, 1806452(2020).
[9]T. Volk and M. Wohlecke, Lithium niobate: defects, photorefraction and ferroelectric switching, Vol. 115 (Springer Science & Business Media, 2008).
[10]L. Arizmendi, Phys. Status Solidi A 201, 253 (2004).
[11]D. Zhu, L. Shao, M. Yu, R. Cheng, B. Desiatov, C. J. Xin, Y. Hu, J. Holzgrafe, S. Ghosh, A. Shams-Ansari, E. Puma, N. Sinclair, C. Reimer, M. Zhang, and M. Lončar, Adv. Opt. Photon. 13, 242 (2021).
[12]D. A. Bryan, R. Gerson, and H. E. Tomaschke, Appl. Phys. Lett. 44, 847 (1984).
[13]H. Hu, A. P. Milenin, R. B. Wehrspohn, H. Hermann, and W. Sohler, J. Vac. Sci. Technol. A. 24, 1012 (2006).
[14]O. Espeso, G. Garcia, A. Climent, F. Agullo-Lopez, G. de la Paliza, J. M. Cabrera, and T. Sajavaara, J. Appl. Phys. 94, 7710 (2003).
[15]J. Cabrera, J. Olivares, M. Carrascosa, J. Rams, R. Muller, and E. Dieguez, Adv. Phys. 45, 349 (1996).
[16]L. Dorrer, P. Tuchel, E. Huger, R. Heller, and H. Schmidt, J. Appl. Phys. 129, 135105 (2021).
[17]L. Cai, Y. Kang, and H. Hu, Opt. Express 24, 4640 (2016).
[18]Z. Ren, P. J. Heard, and S. Yu, J. Vac. Sci. Technol. B. 25, 1161 (2007).
[19]M. Levy, J. Osgood, R. M., R. Liu, L. E. Cross, I. Cargill, G. S., A. Kumar, and H. Bakhru, Appl. Phys. Lett. 73, 2293 (1998).
[20]M. Levy and R. M. Osgood, Crystal ion-slicing of single-crystal films (2000).
[21]P. Rabiei and P. Gunter, Appl. Phys. Lett. 85, 4603 (2004).
[22]R. Nehra, R. Sekine, L. Ledezma, Q. Guo, R. M. Gray, A. Roy, and A. Marandi, Science 377, 1333 (2022).
[23]C. Wang, M. Zhang, X. Chen, M. Bertrand, A. Shams-Ansari, S. Chandrasekhar, P. Winzer, and M. Lončar, Nature 562, 101 (2018).
[24]R. Sekine, R. M. Gray, L. Ledezma, S. Zhou, Q. Guo, and A. Marandi, Multi-octave frequency comb from an ultra-low-threshold nanophotonic parametric oscillator (2023), arXiv:2309.04545 [physics.optics].
[25]T.-H. Wu, L. Ledezma, C. Fredrick, P. Sekhar, R. Sekine, Q. Guo, R. M. Briggs, A. Marandi, and S. A. Diddams, Nat. Photonics 18, 218 (2024).
[26]M. Jankowski, C. Langrock, B. Desiatov, A. Marandi, C. Wang, M. Zhang, C. R. Phillips, M. Lončar, and M. M. Fejer, Optica 7, 40 (2020).
[27]M. Yu, D. Barton III, R. Cheng, C. Reimer, P. Kharel, L. He, L. Shao, D. Zhu, Y. Hu, H. R. Grant, L. Johansson, Y. Okawachi, A. L. Gaeta, M. Zhang, and M. Lončar, Nature 612, 252 (2022).
[28]Q. Guo, B. K. Gutierrez, R. Sekine, R. M. Gray, J. A. Williams, L. Ledezma, L. Costa, A. Roy, S. Zhou, M. Liu, and A. Marandi, Science 382, 708 (2023).
[29]H. Hu, A. P. Milenin, R. B. Wehrspohn, H. Hermann, and W. Sohler, J. Vac. Sci. Technol. A. 24, 1012 (2006).
[30]M. Mahmoud, L. Cai, C. Bottenfield, and G. Piazza, IEEE Photonics J. 10, 1 (2018).
[31]D. Jun, J. Wei, C. Eng Png, S. Guangyuan, J. Son, H. Yang, and A. J. Danner, J. Vac. Sci. Technol. B. 30, 011208 (2012).
[32]Z. Ren, P. J. Heard, J. M. Marshall, P. A. Thomas, and S. Yu, J. Appl. Phys. 103, 034109 (2008).
[33] A. Aryal, I. Stricklin, M. Behzadirad, D. W. Branch, A. Siddiqui, and T. Busani, Nanomaterials 12, 10.3390/nanol2162836 (2022).
[34]G. Ulliac, V. Calero, A. Ndao, F. Baida, and M.-P. Bernal, Opt. Mater. 53, 1 (2016).
[35]C. Wang, C. Langrock, A. Marandi, M. Jankowski, M. Zhang, B. Desiatov, M. M. Fejer, and M. Lončar, Optica 5, 1438 (2018).
[36] A. Shams-Ansari, G. Huang, L. He, Z. Li, J. Holzgrafe, M. Jankowski, M. Churaev, P. Kharel, R. Cheng, D. Zhu, N. Sinclair, B. Desiatov, M. Zhang, T. J. Kippenberg, and M. Lončar, APL Photonics 7, 081301 (2022).
[37]K. J. Kanarik, S. Tan, and R. A. Gottscho, J. Phys. Chem. Lett. Letters 9, 4814 (2018).
[38]S. M. George, Accounts Chem. Res. 53, 1151 (2020).
[39]K. J. Kanarik, T. Lill, E. A. Hudson, S. Sriraman, S. Tan, J. Marks, V. Vahedi, and R. A. Gottscho, J. Vac. Sci. Technol. A. 33, 020802 (2015).
[40]X. Sang and J. P. Chang, J. Phys. D. Appl. Phys. 53, 183001 (2020).
[41]Y. Horiike, T. Tanaka, M. Nakano, S. Iseda, H. Sakaue, A. Nagata, H. Shindo, S. Miyazaki, and M. Hirose, J. Vac. Sci. Technol. A. 8, 1844 (1990).
[42]G. S. Oehrlein, D. Metzler, and C. Li, ECS J. Solid State Sc. 4, N5041 (2015).
[43]J. A. Michaels, N. Delegan, Y. Tsaturyan, J. R. Renzas, D. D. Awschalom, J. G. Eden, and F. J. Heremans, J. Vac. Sci. Technol. A. 41, 032607 (2023).
[44]J. W. DuMont, A. E. Marquardt, A. M. Cano, and S. M. George, ACS Appl. Mater. Inter. 9, 10296 (2017).
[45]R. Rahman, E. C. Mattson, J. P. Klesko, A. Dangerfield, S. Rivillon-Amy, D. C. Smith, D. Hausmann, and Y. J. Chabal, ACS Appl. Mater. Inter. 10, 31784 (2018).
[46]K. K. Ko and S. W. Pang, J. Vac. Sci. Technol. B. 11, 2275 (1993).
[47]S. D. Park, C. K. Oh, J. W. Bae, G. Y. Yeom, T. W. Kim, J. I. Song, and J. H. Jang, Appl. Phys. Lett. 89, 043109 (2006).
[48]S. D. Park, C. K. Oh, W. S. Lim, H. C. Lee, J. W. Bae, G. Y. Yeom, T. W. Kim, J. I. Song, and J. H. Jang, Appl. Phys. Lett. 91, 013110 (2007).
[49]W. Lu, Y. Lee, J. C. Gertsch, J. A. Murdzek, A. S. Cavanagh, L. Kong, J. A. del Alamo, and S. M. George, Nano. Lett. 19, 5159 (2019).
[50]T. Meguro, M. Ishii, T. Sugano, K. Gamo, and Y. Aoyagi, Appl. Surf. Sci. 82-83, 193 (1994).
[51]Y. Aoyagi, K. Shinmura, K. Kawasaki, T. Tanaka, K. Gamo, S. Namba, and I. Nakamoto, Appl. Phys. Lett. 60, 968 (1992).
[52]M. R. Aziziyan, H. Sharma, and J. J. Dubowski, ACS Appl. Mater. Inter. 11, 17968 (2019).
[53]C. Li, D. Metzler, C. S. Lai, E. A. Hudson, and G. S. Oehrlein, J. Vac. Sci. Technol. A. 34, 041307 (2016).
[54] A. I. Abdulagatov and S. M. George, J. Vac. Sci. Technol. A. 38, 022607 (2020).
[55]Y. Ishii, K. Okuma, T. Saldana, K. Maeda, N. Negishi, and J. Manos, Jpn. J. Appl. Phys. 56, 06HB07 (2017).
[56]S. D. Sherpa and A. Ranjan, J. Vac. Sci. Technol. A. 35, 01A102 (2016).
[57]T. Matsuura, Y. Honda, and J. Murota, Appl. Phys. Lett. 74, 3573 (1999).
[58]D. N. Shanks, R. K. Ahmed, J. D. Femi-Oyetoro, M. R. Dickie, A. D. Beyer, and F. Greer, J. Vac. Sci. Technol. A. 41, 052601 (2023).
[59]D. R. Zywotko, J. Faguet, and S. M. George, J. Vac. Sci. Technol. A. 36, 061508 (2018).
[60]T. Ohba, W. Yang, S. Tan, K. J. Kanarik, and K. Nojiri, Jpn. J. Appl. Phys. 56, 06HB06 (2017).
[61]K. J. Kanarik, S. Tan, W. Yang, T. Kim, T. Lill, A. Kabansky, E. A. Hudson, T. Ohba, K. Nojiri, J. Yu, R. Wise, I. L. Berry, Y. Pan, J. Marks, and R. A. Gottscho, J. Vac. Sci. Technol. A. 35, 05C302 (2017).
[62] A. A. Hossain, H. Wang, D. S. Catherall, M. Leung, H. C. M. Knoops, J. R. Renzas, and A. J. Minnich, J. Vac. Sci. Technol. A. 41, 062601 (2023).
[63]H. Wang, A. Hossain, D. Catherall, and A. J. Minnich, J. Vac. Sci. Technol. A. 41, 032606 (2023).
[64]M. Konh, Y. Wang, H. Chen, S. Bhatt, J. Q. Xiao, and A. V. Teplyakov, Appl. Surf. Sci. 575, 151751 (2022).
[65]S. H. Gerritsen, N. J. Chittock, V. Vandalon, M. A. Verheijen, H. C. M. Knoops, W. M. M. Kessels, and A. J. M. Mackus, ACS Appl. Nano Mater. 5, 18116 (2022).
[66]H. Turčičová, J. Zemek, J. Tóth, and I. Drbohlav, Surf. Interface Anal. 34, 468 (2002).
[67]R. G. Gruenke, O. A. Hitchcock, E. A. Wollack, C. J. Sarabalis, M. Jankowski, T. P. McKenna, N. R. Lee, and A. H. Safavi-Naeini, Sci. Rep. 14, 6663 (2024).
[68]N. J. Chittock, Y. Shu, S. D. Elliott, H. C. M. Knoops, W. M. M. E. Kessels, and A. J. M. Mackus, J. Appl. Phys. 134, 075302 (2023).
[69] A. A. Osipov, A. A. Osipov, G. A. Iankevich, A. B. Speshilova, A. Shakhmin, V. I. Berezenko, and S. E. Alexandrov, J. Microelectromech. S. 30, 90 (2021).
[70]P. C. Karulkar, J. Vac. Sci. Technol. B. 18, 169 (1981).
[71]N. Kaufherr, D. J. Eichorst, and D. A. Payne, J. Vac. Sci. Technol. A. 14, 299 (1996).
[72]N. X. ray Photoelectron Spectroscopy Database, Gaithersburg MD, 20899 (2000).
[73]E. Skryleva, I. Kubasov, P. Kiryukhantsev-Korneev, B. Senatulin, R. Zhukov, K. Zakutailov, M. Malinkovich, and Y. Parkhomenko, Appl. Surf. Sci. 389, 387 (2016).
[74]J. Moulder and J. Chastain, Handbook of X-ray Photoelectron Spectroscopy: A Reference Book of Standard Spectra for Identification and Interpretation of XPS Data (Physical Electronics Division, Perkin-Elmer Corporation, 1992).
[76] Visible-to-mid-IR tunable frequency comb in nanophotonics Arkadev Roy et, al, Nature Communications volume 14, Article number: 6549 (2023)
[77] Di Zhu, Linbo Shao, Mengjie Yu, Rebecca Cheng, Boris Desiatov, C. J. Xin, Yaowen Hu, Jeffrey Holzgrafe, Soumya Ghosh, Amirhassan Shams-Ansari, Eric Puma, Neil Sinclair, Christian Reimer, Mian Zhang, and Marko Lončar, “Integrated photonics on thin-film lithium niobate,” Adv. Opt. Photon. 13, 242-352 (2021)
[78] Plasma Pro 100 brochure. https://plasma.oxinst.com/products/ale/plasmapro-100ale?gad_source=1&gclid=EAIaIQobChMI6MuvtcP8iAMVnRKHAx1ZWRn4EAAY ASAAEgK5IPD_BwE
[79] https://pubs.acs.org/doi/10.1021/acs.jpclett.8b00997

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method of etching lithium niobate, comprising:
etching a substrate comprising lithium niobate using atomic layer etching.

2. The method of claim 1, wherein the etching comprises patterning a photonic integrated circuit or one or more device structures in the lithium niobate and/or smoothing the surface of one or more device structures that have been patterned by another process.

3. The method of claim 1, wherein the etching comprises:
(a) exposing the lithium niobate to a hydrogen plasma comprising protons accelerated by a bias in an ALE reactor, to form a modified layer on the lithium niobate substrate;
(b) purging the reactor using an inert gas;
(c) removing the modified layer using a removal agent; and
(d) purging the reactor using an inert gas.

4. The method of claim 3, wherein the removing comprises sputtering using chemical species or using ions accelerated by a bias under conditions that remove the modified layer over the bulk lithium niobate in a self-limiting process.

5. The method of claim 3, wherein the removing comprises exposing the modified layer to the removal agent comprising chlorine or fluorine as a neutral species or in a plasma as an ionic species accelerated by a bias.

6. The method of claim 3, wherein the inert gas comprises argon.

7. The method of claim 3, further comprising performing multiple cycles of step (a) and (b) prior to performing step (c).

8. The method of claim 3, further comprising performing multiple cycles of step (a) and (c).

9. The method of claim 1, wherein an etched surface of the lithium niobate is etched with nanometer resolution (or with a surface roughness less than 3.5 nm, less than 2 nm, less than 1.5 nm, or less than 1 nm, and/or the etched surface is smoother than the non etched regions).

10. The method of claim 1, further comprising one or more cycles of:
(a) exposure of the substrate to a dose of the hydrogen plasma for a duration and under a bias and temperature and pressure such that the hydrogen adsorbs on a surface of the substrate in a self limiting process as characterized by the hydrogen saturating all available reactive bonding sites with the lithium niobate to form a modified layer; and
(b) exposure of the modified layer to a dose of the chemical species comprising a halogen at a temperature, pressure and energy such that the chemical species selectively removes the modified layer over the underlying bulk lithium niobate in a self-limiting process; and
such that removal of one or more atomic layers of the lithium niobate after each cycle can be controlled with precision of a single one of the atomic layers.

11. The method of claim 2, wherein the photonic integrated circuit or device structure includes at least one of a waveguide or resonator.

12. The method of claim 1, wherein the ALE is performed on an x-cut surface of the lithium niobate.

13. The method of claim 3, further comprising controlling an angle of incidence or angular distribution of the removal agent on the substrate by controlling at least one of the temperature or pressure or bias, so as to control anisotropy and/or inclination of the etched surface and crystal quality of the etched lithium niobate.

14. The method of claim 3, wherein the removing comprises a selective process that removes redeposited species without etching the lithium niobate in the substrate.

15. The method of claim 14, wherein the removing comprises thermal cycling or wet etching using a liquid removal agent.

16. The method of claim 3, further comprising selecting an angle of incidence or angular distribution of the reactant/and or removal agent on the substrate to etch and/or smoothen sidewalls of a waveguide or structure comprising the lithium niobate.

17. The method of claim 3, wherein the removal agent comprises SF6/argon.

18. A device comprising:
a structure patterned into a lithium niobate substrate using atomic layer etching, or
a structure comprising lithium niobate having a surface smoothened using atomic layer etching.

19. The device of claim 18 wherein the surface of the lithium niobate comprises at least one of hydrogen, an amorphized or amorphous layer, or a surface roughness less than 3.5 nm or less than 1.5 nm.

20. An atomic layer etching apparatus:
a source of a reactant for reacting with a surface of a substrate so as to form a modified layer on the substrate, wherein the reactant is generated by a plasma, and the substrate comprises lithium niobate;
a source of a treatment for removing the modified layer; and
a computer comprising a non-transitory computer readable medium storing a plurality of instructions, the plurality of instructions comprising:
outputting the reactant in the reactor tool,
outputting the treatment to remove the modified layer so as to etch and/or smooth features in the lithium niobate.
